(19) United States
(12) Patent Application Publication
(10) Pub. No.: US 2020/0013932 A1
(43) Pub. Date: Jan. 9, 2020

(54) SEMICONDUCTOR DEVICE PACKAGE

(71) Applicant: LG INNOTEK CO., LTD., Seoul (KR)

(72) Inventors: Ji Hyung MOON, Seoul (KR); Kyoung Un KIM, Seoul (KR); Sun Woo PARK, Seoul (KR); June O SONG, Seoul (KR); Sun Woo OH, Seoul (KR); Sang Jun LEE, Seoul (KR); Hwan Hee JEONG, Seoul (KR); Myung Ho HAN, Seoul (KR)

(21) Appl. No.: 16/480,485

(22) PCT Filed: Jan. 17, 2018
(86) PCT No.: PCT/KR2018/000794

§ 371 Date: Jul. 24, 2019

(30) Foreign Application Priority Data
Jan. 24, 2017 (KR) 10-2017-0010790
Mar. 24, 2017 (KR) 10-2017-0037535

(51) Int. Cl. H01L 33/50; H01L 33/56; H01L 33/32; H01L 33/10; H01L 33/60; H01L 33/62; H01L 27/15

(52) U.S. Cl. CPC H01L 33/504; H01L 33/508; H01L 33/56; H01L 27/156; H01L 33/10; H01L 33/60; H01L 33/62; H01L 33/32

(57) ABSTRACT

A semiconductor device package according to the present invention comprises: a semiconductor device including a substrate, a light-emitting structure, and a first pad and second pad electrically connected to the light-emitting structure; a wavelength converting unit disposed to surround the upper surface and side surfaces of the semiconductor device; and a light control unit disposed on the wavelength converting unit, wherein the wavelength converting unit may include an upper surface spaced a first spacing interval apart in a vertical direction from the semiconductor device, and a side surface spaced a second spacing interval apart in a horizontal direction from the semiconductor device. The present invention relates to a semiconductor device package and a light source module. A semiconductor device package according to the present invention may include a semiconductor device for emitting light, a wavelength converting unit, and a light control unit and may emit white light in directions of four side surfaces surrounding the wavelength converting unit and in an upward direction of the light control unit. A wavelength converting unit according to the present invention may be disposed at the upper surface of a semiconductor device and four side surfaces surrounding the semiconductor device, receive light emitted from the semiconductor device and incident thereto and diffuse the received light, convert the wavelength of light incident thereto and provide the converted light, and emit white light in four side surface directions and in an upward direction. A light control unit according to the present invention may be disposed on the upper surface of a wavelength converting unit, reflect a part of white light incident thereon from the wavelength converting unit, and transmit a part of the white light.

### TECHNICAL FIELD

The present invention relates to a semiconductor device package, a light source module, and a display device.

### BACKGROUND ART

A semiconductor device including a compound such as GaN, AlGaN or the like may be diversely used as a light emitting diode, a light receiving element and various kinds of diodes since it has many advantages such as band gap energy that is wide and easy to adjust.

Particularly, a light emitting device, such as a light emitting diode or a laser diode using a group III-V or group II-VI compound semiconductor material, has an advantage of implementing light of various wavelength bands, such as red light, green light, blue light, infrared light and ultraviolet light, owing to development of thin film growth techniques and device materials. In addition, the light emitting device, such as a light emitting diode or a laser diode using a group III-V or group II-VI compound semiconductor material, is also able to implement a white light source having a good efficiency by using a fluorescent material or combining colors. The light emitting device like this has advantages of low power consumption, semi-permanent lifespan, rapid response speed, stability, and environmental friendliness, compared with existing light sources such as fluorescent lamps, incandescent lamps and the like.

Furthermore, when a light receiving device, such as an optical detector or a solar cell, is manufactured using a group III-V or group II-VI compound semiconductor material, light of various wavelength regions, from a gamma ray to a radio wavelength region, can be used since the light receiving device absorbs light of various wavelength regions and generates optical current owing to development of device materials. In addition, since the light receiving device like this has advantages of rapid response speed, stability, environmental friendliness, and easy adjustment of device materials, it can be easily used for power control, microwave circuits or communication modules.

Accordingly, application of the semiconductor device is expanded to transmission modules of optical communication means, light emitting diode backlights substituting for cold cathode fluorescence lamps (CCFL) configuring the backlight of a liquid crystal display (LCD) device, white LED lighting devices substituting for fluorescent lamps, incandescent lamps, headlights or signal lights of a vehicle, sensors for sensing gas or fire and the like. In addition, application of the semiconductor device may be expanded to high frequency application circuits, other power control devices and communication modules.

A light emitting device may be provided as a p-n junction diode having a characteristic of converting electric energy to light energy using an element of group III-V or group II-VI on the periodic table and may implement various wavelengths by adjusting the composition ratio of a compound semiconductor.

Meanwhile, supply of thin film products is requested in a display device or the like including a light source module. In the case of a display device which needs a light source module, the light source module, as well as a display panel, should be implemented in the form of a thin film.

### DISCLOSURE OF INVENTION

### Technical Problem

Therefore, the present invention has been made in view of the above problems, and an object of the present invention is to provide a semiconductor device package and a light source module, which can provide light toward side surfaces.

Another object of the present invention is to provide a semiconductor device package and a light source module, which can improve light extraction efficiency and white light conversion efficiency of a semiconductor device.

Another object of the present invention is to provide a semiconductor device package and a light source module, which can improve speed of light.

### Technical Solution

To accomplish the above objects, according to one aspect of the present invention, there is provided a semiconductor device package comprising: a semiconductor device including a substrate, a light emitting structure, and a first pad and a second pad electrically connected to the light emitting structure; a wavelength conversion unit disposed to surround a top surface and side surfaces of the semiconductor device; and a light control unit disposed on the wavelength converting unit, wherein the wavelength conversion unit may include a top surface having a first separation distance from the semiconductor device in a vertical direction, and side surfaces having a second separation distance from the semiconductor device in a horizontal direction.

The semiconductor device package may include first light emitted toward the top surface and second light emitted toward the side surfaces, wherein intensity of the first light may be higher than intensity of the second light.

The first separation distance may be larger than the second separation distance.

A ratio of the second separation distance to the first separation distance may be between 1:0.01 and 1:100.

The wavelength conversion unit may include a resin, a wavelength conversion material, and a scattering material, and the light control unit may include a resin of a series the same as that of a resin included in the wavelength conversion unit.

The wavelength conversion unit may include: a second wavelength conversion unit disposed on the top surface of the semiconductor device and including a wavelength conversion material; and a first wavelength conversion unit disposed on a light-transmitting member and including a wavelength conversion material, wherein a content ratio of the wavelength conversion material of the first wavelength conversion unit is different from that of the second wavelength conversion unit.

The second wavelength conversion unit disposed in a region of a top surface of the first wavelength conversion unit may be vertically overlapped on the top surface of the first wavelength conversion unit within a range less than 50% of a width of the first wavelength conversion unit.

The wavelength conversion material may be a fluorescent substance, and when the first wavelength conversion unit and the second wavelength conversion unit are divided into region ‘a’ having only the first wavelength conversion unit, region ‘b’ in which a portion of the first wavelength conversion unit is vertically overlapped with a portion of the second wavelength conversion unit, and region ‘c’ having only the second wavelength conversion unit, each of the three regions may have a different fluorescent substance content ratio (an average content ratio in the case of region ‘b’).

A content ratio of the fluorescent substance to a polymer resin of each region (an average content ratio in the case of region ‘b’) may be a relative content ratio of region ‘c’>region ‘b’>region ‘a’ or region ‘c’>region ‘a’>region ‘b’.

The inclined surface may have an angle of 15 to 75 degrees with respect to a top surface of the first pad and the second pad.

### Advantageous Effects

According to a semiconductor device package of the present invention, light can be provided toward side surfaces.

According to a semiconductor device package of the present invention, light extraction efficiency and white light conversion efficiency of a semiconductor device can be improved.

According to a semiconductor device package of the present invention, the semiconductor device package can be manufactured in the form of a thin film.

According to a semiconductor device package of the present invention, the manufacturing process can be simplified, and the manufacturing cost can be reduced.

According to a semiconductor device package of the present invention, speed of light and an orientation angle can be adjusted by adjusting an inclined surface angle.

### BRIEF DESCRIPTION OF THE DRAWINGS

FIG. 1 is a view showing the cross-section of a semiconductor device according to an embodiment of the present invention.

FIG. 2 is a view showing a semiconductor device package according to a first embodiment of the present invention.

FIG. 3 is a view showing the cross-section taken along the line A-A of the semiconductor device package shown in FIG. 2.

FIG. 4 is a view showing the cross-section taken along the line B-B of the semiconductor device package shown in FIG. 2.

FIG. 5 is a view showing an example of a light control unit included in a semiconductor device package according to a first embodiment of the present invention.

FIG. 6 is a view showing another example of a light control unit included in a semiconductor device package according to a first embodiment of the present invention.

FIG. 7 is a view showing still another example of a light control unit included in a semiconductor device package according to a first embodiment of the present invention.

FIG. 8 is a view showing another example of a semiconductor device package according to a first embodiment of the present invention.

FIG. 9 is a view showing still another example of another semiconductor device package according to a first embodiment of the present invention.

FIG. 10 is a plan view showing a semiconductor device package according to a second embodiment of the present invention.

FIG. 11 is a view showing the cross-section taken along the line A-A′ of the semiconductor device package according to a second embodiment of the present invention shown in FIG. 10.

FIG. 12 is a view showing the cross-section of a semiconductor device package according to a first comparative example.

FIG. 13 is a view showing the cross-section of a semiconductor device package according to a second comparative example.

FIG. 14 is a view describing a semiconductor device package according to a second comparative example.

FIG. 15 is a view describing the process of manufacturing a semiconductor device package according to a second comparative example.

FIG. 16 is a view showing a light source module according to an embodiment of the present invention.

FIG. 17 is a view showing an example of a light guide panel applied to a light source module according to an embodiment of the present invention.

### BEST MODE FOR CARRYING OUT THE INVENTION

Details of the objects and technical configuration of the present invention described above and operational effects according thereto will be more clearly understood hereinafter by the detailed description.

In describing the present invention, the terms such as “first”, “second” and the like used below are only identification symbols for distinguishing the same or corresponding constitutional components, and the same or corresponding constitutional components are not limited by the terms such as “first”, “second” and the like.

A singular expression includes a plural expression unless the context clearly indicates otherwise. The terms “include”, “have” and the like are to specify presence of features, integers, steps, operations, constitutional components, parts and combinations of these stated in the specification, and it may be interpreted such that one or more other features, integers, steps, operations, constitutional components, parts, and combinations of these can be added.

The terms “comprises” and/or “comprising” used hereinafter means that the mentioned constitutional components, steps, operations and/or elements do not preclude presence or addition of one or more other constitutional components, steps, operations and/or elements.

In describing the present invention, if a substrate, a layer (film), a region, a pattern or a structure is referred to as being formed or disposed “up/on” or “down/under” another substrate, layer (film), region, pad or pattern, it can be “directly” formed or disposed “on” or “under” the other element or “indirectly” formed or disposed with the intervention of other layer. The reference of “up/on” or “down/under” of each layer is described on the basis of the drawings.

Hereinafter, a semiconductor device package, a light source module, and a display device according to an embodiment of the present invention will be described in detail with reference to the accompanying drawings.

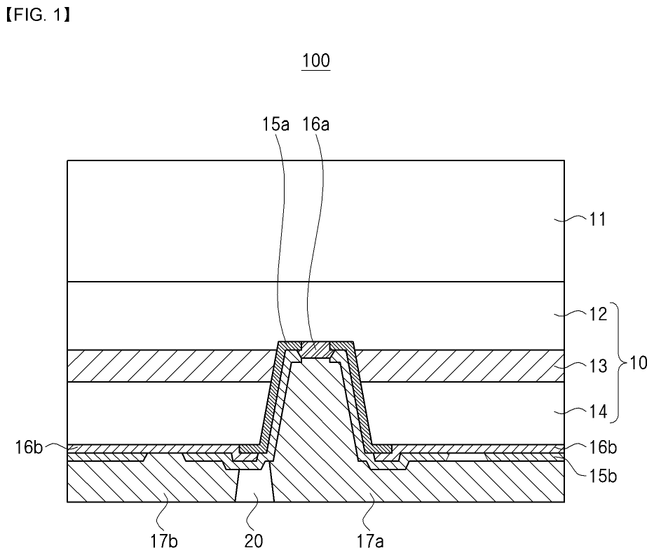

A semiconductor device according to an embodiment of the present invention will be described with reference to FIG. 1.

FIG. 1 is a view showing the cross-section of a semiconductor device according to an embodiment of the present invention.

A semiconductor device 100 according to an embodiment may include a substrate 11, a light emitting structure 10, a first electrode 16a, and a second electrode 16b as shown in FIG. 1.

The light emitting structure 10 according to an embodiment may include a first conductive semiconductor layer 12, an active layer 13, and a second conductive semiconductor layer 14. The light emitting structure 10 according to an embodiment may include the active layer disposed between the first conductive semiconductor layer 12 and the second conductive semiconductor layer 14.

For example, according to the light emitting structure 10 according to an embodiment, the first conductive semiconductor layer 12 may be provided as an n-type semiconductor layer, and the second conductive semiconductor layer 14 may be provided as a p-type semiconductor layer. In addition, according to another example of the light emitting structure 10 according to an embodiment, the first conductive semiconductor layer 12 may be provided as a p-type semiconductor layer, and the second conductive semiconductor layer 14 may be provided as an n-type semiconductor layer.

In the light emitting structure 10, a wavelength band of emitted light may be changed according to a material constituting the active layer 13. In addition, selection of a material constituting the first conductive semiconductor layer 12 and the second conductive semiconductor layer 14 may be changed according to a material constituting the active layer 13. The light emitting structure 10 may be provided as a compound semiconductor. The light emitting structure 10 may be provided as, for example, a group II-VI or group III-V compound semiconductor. For example, the light emitting structure 10 may be provided to include at least two or more elements selected among aluminum Al, gallium Ga, indium In, phosphorous P, arsenic As and nitrogen N.

The active layer 13 may generate light of a wavelength band corresponding to recombination of first carriers (e.g., electrons) provided from the first conductive semiconductor layer 12 and second carriers (e.g., holes) provided from the second conductive semiconductor layer 14. The active layer 13 may be provided as any one among a single well structure, a multiple well structure, a quantum dot structure, and a quantum wire structure. The active layer 13 may be provided as a compound semiconductor. The active layer 13 may be provided as, for example, a group II-VI or group III-V compound semiconductor.

When light of an ultraviolet wavelength band, a blue wavelength band or a green wavelength band is generated from the active layer 13, the active layer 13 may be provided as a semiconductor material having a composition formula of, for example, InxAlyGa1-x-yN (0≤x≤1, 0≤y≤1, 0≤x+y≤1). The active layer 13 may be selected from a group including, for example, InAlGaN, InAlN, InGaN, AlGaN and GaN. When the active layer 13 is provided as a multiple well structure, the active layer 13 may be provided by stacking a plurality of barrier layers and a plurality of well layers.

The first conductive semiconductor layer 12 may be provided as a compound semiconductor. The first conductive semiconductor layer 12 may be provided as, for example, a group II-VI compound semiconductor or a group III-V compound semiconductor. For example, when light of an ultraviolet wavelength band, a blue wavelength band or a green wavelength band is generated from the active layer 13, the first conductive semiconductor layer 12 may be provided as a semiconductor material having a composition formula of In xAlyGa1-x-yN (0≤x≤1, 0≤y≤1, 0≤x+y≤1). The first conductive semiconductor layer 12 may be selected from a group including, for example, GaN, AlN, AlGaN, InGaN, InN, InAlGaN and AlInN, and an n-type dopant, such as Si, Ge, Sn, Se, Te or the like, may be doped therein.

The second conductive semiconductor layer 14 may be provided as a compound semiconductor. The second conductive semiconductor layer 14 may be provided as, for example, a group II-VI compound semiconductor or a group III-V compound semiconductor. For example, when light of an ultraviolet wavelength band, a blue wavelength band or a green wavelength band is generated from the active layer 13, the second conductive semiconductor layer 14 may be provided as a semiconductor material having a composition formula of In xAlyGa1-x-yN (0≤x≤1, 0≤y≤1, 0≤x+y≤1). The second conductive semiconductor layer 14 may be selected from a group including, for example, GaN, AlN, AlGaN, InGaN, InN, InAlGaN and AlInN, and a p-type dopant, such as Mg, Zn, Ca, Sr, Ba or the like, may be doped therein.

As shown in FIG. 1, the semiconductor device 100 according to an embodiment may include the first electrode 16a electrically connected to the first conductive semiconductor layer 12 and the second electrode 16b electrically connected to the second conductive semiconductor layer 14. In addition, the semiconductor device 100 according to an embodiment may include a first pad 17a electrically connected to the first electrode 16a and a second pad 17b electrically connected to the second electrode 16b. A filler layer 20 may be disposed between the first pad 17a and the second pad 17b. The filler layer 20 may be provided as, for example, an insulation material. The filler layer 20 may support the first pad 17a and the second pad 17b.

According to the semiconductor device 100 according to an embodiment, as shown in FIG. 1, the light emitting structure 10 may be disposed under the substrate 11. The substrate 11 may include a conductive substrate or an insulating substrate. For example, the substrate 11 may be a material suitable for growth of the light emitting structure 10 or a carrier wafer. The substrate 11 may be formed of a material selected from a group including sapphire (Al2O3), SiC, GaAs, GaN, ZnO, Si, GaP, InP and Ge.

The first electrode 16a may electrically contact with the first conductive semiconductor layer 12 through a through hole passing through the active layer 13 and the second conductive semiconductor layer 14. A first insulation layer 15a may be disposed on the side surfaces of the first conductive semiconductor layer 12, the active layer 13, and the second conductive semiconductor layer 14. The first insulation layer 15a may prevent the active layer 13 and the second conductive semiconductor layer 14 from contact with the first electrode 16a and the first pad 17a.

The first electrode 16a and the second electrode 16b may include at least one among a group including Ag, Ni, Al, Rh, Pd, Ir, Ru, Mg, Zn, Pt, Au, Hf, Ti, Cr, Cu, and a selective combination of these.

A second insulation layer 15b may be further disposed between the second electrode 16b and the first pad 17a. In addition, the second insulation layer 15b may also be disposed between the second electrode 16b and the second pad 17b. The second insulation layer 15b may be provided as a material performing both an insulation function and a reflection function. For example, the second insulation layer 15b may include a DBR layer.

In the semiconductor device 100 according to an embodiment, as shown in FIG. 1, the substrate 11 may be disposed on the top, and the first pad 17a and the second pad 17b may be disposed on the bottom. For example, the semiconductor device 100 may be electrically connected to a circuit substrate disposed on the bottom through a flip chip bonding method. In addition, as the second insulation layer 15b disposed on the first pad 17a and the second pad 17b is provided as a DBR layer having a good reflection characteristic, light generated by the active layer 10 may be effectively emitted toward the side surface and toward the top of the light emitting structure 10.

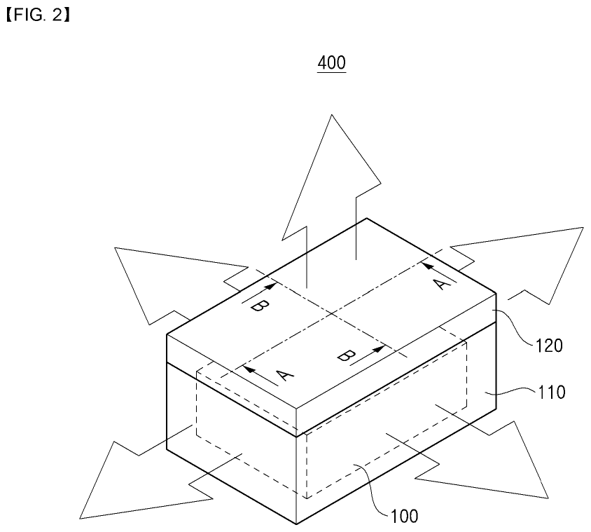

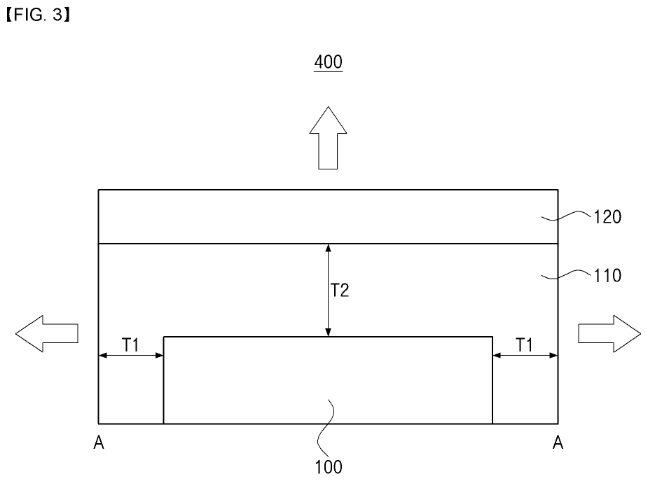

First, a semiconductor device package according to a first embodiment will be described with reference to FIGS. 2 to 4. FIG. 2 is a view showing a semiconductor device package according to a first embodiment of the present invention, FIG. 3 is a cross-sectional view taken along the line A-A of the semiconductor device package shown in FIG. 2, and FIG. 4 is a cross-sectional view taken along the line B-B of the semiconductor device package shown in FIG. 2.

A semiconductor device package 400 according to a first embodiment may include a semiconductor device 100, a wavelength conversion unit 110, and a light control unit 120 as shown in FIGS. 2 to 4.

For example, a pad may be disposed on the bottom surface of the semiconductor device 100, and the semiconductor device package 400 according to an embodiment may be manufactured in a chip scale package (CSP) method.

The semiconductor device 100 may include a light emitting structure for generating and emitting light. For example, the semiconductor device 100 may emit light of a blue wavelength band. The semiconductor device 100 may include a first pad 17a and a second pad 17b disposed on the bottom surface. The first pad 17a may be electrically connected to a first conductive semiconductor layer 12 of the light emitting structure, and the second pad 17b may be electrically connected to a second conductive semiconductor layer 14 of the light emitting structure. For example, the semiconductor device 100 may be supplied with power from a circuit substrate that will be disposed on the bottom and may be electrically connected to the circuit substrate that will be disposed on the bottom in a flip chip bonding method.

The semiconductor device package according to a first embodiment may include first light emitted toward the top surface and second light emitted toward the side surfaces.

Although intensity of the first light may be higher than the intensity of the second light, it is not limited thereto.

The wavelength conversion unit 110 according to a first embodiment may be disposed around the semiconductor device 100. The wavelength conversion unit 110 may be disposed on the side surfaces of the semiconductor device 100. The wavelength conversion unit 110 may be disposed on the four side surfaces surrounding the semiconductor device 100.

The wavelength conversion unit 110 may be disposed on the top surface of the semiconductor device 100. The wavelength conversion unit 110 may surround the semiconductor device 100 to cover the top surface and the four side surfaces of the semiconductor device 100.

For example, the wavelength conversion unit 110 may be disposed to directly contact with the top surface of the semiconductor device 100. The bottom surface of the wavelength conversion unit 110 may be disposed to directly contact with the top surface of the semiconductor device 100. In addition, the wavelength conversion unit 110 may include a kind of side wall disposed on the side surfaces of the semiconductor device 100. All the four side surfaces of the semiconductor device 100 may be disposed to be surrounded by the four side walls of the wavelength conversion unit 110. The side walls of the wavelength conversion unit 110 may be disposed to directly contact with the side surfaces of the semiconductor device 100. The inner surfaces of the side walls of the wavelength conversion unit 110 may be disposed to directly contact with the side surfaces of the semiconductor device 100.

The wavelength conversion unit 110 may receive light emitted from the semiconductor device 100. The wavelength conversion unit 110 may include a scattering material. The wavelength conversion unit 110 may scatter the light inputted from the semiconductor device 100. The wavelength conversion unit 110 may include a wavelength conversion material. The wavelength conversion unit 110 may wavelength-convert and emit the light inputted from the semiconductor device 100. For example, the wavelength conversion unit 110 may receive light of a blue band from the semiconductor device 100 and emit light of a yellow band.

The wavelength conversion unit 110 may provide white light generated from the light of a blue band and the light of a yellow band. The wavelength conversion unit 110 may emit the white light toward the four side surfaces and toward the top as shown in FIGS. 2 to 4.

The wavelength conversion unit 110 may emit the white light from the four side walls toward the outside. The side walls of the wavelength conversion unit 110 may be provided at a first thickness T1 or a third thickness T3. The wavelength conversion unit 110 may include an upper region disposed on the four side walls. The upper region of the wavelength conversion unit 110 may be provided at a second thickness T2.

For example, the first separation distance T1 and the third separation distance T3 may be a separation distance of the long axis direction or the short axis direction. According to an embodiment, the first separation distance T1 and the third separation distance T3 may be provided to be the same. In addition, according to another embodiment, the first separation distance T1 and the third separation distance T3 may be provided to be different from each other.

The first separation distance T1 may be defined as a distance from the side surface of the long axis direction of the semiconductor device 100 to the outer surface of the wavelength conversion unit 110. The third separation distance T3 may be defined as a distance from the side surface of the short axis direction of the semiconductor device 100 to the outer surface of the wavelength conversion unit 110. In addition, the second separation distance T2 may be defined as a distance from the top surface of the semiconductor device 100 to the top surface of the wavelength conversion unit 110.

For example, the second separation distance T2 of the upper region of the wavelength conversion unit 110 may be provided in a few micrometers to a few hundred micrometers. The larger the second separation distance T2 of the upper region of the wavelength conversion unit 110, the more the wavelength conversion efficiency may be enhanced. In addition, the larger the second separation distance T2 of the upper region of the wavelength conversion unit 110, the more the thickness of the side surface of the upper region of the wavelength conversion unit 110 increases, and thus the speed of light diffusing toward the side surface of the wavelength conversion unit 110 increases, and the efficiency of emission of light emitted toward the side surface of the semiconductor device 100 can be enhanced. For example, the second separation distance T2 of the wavelength conversion unit 110 may be provided to be 10 to 1,000 micrometers. When the second separation distance T2 of the wavelength conversion unit 110 is smaller than 10 micrometers, the wavelength conversion efficiency may be lowered, and when the second separation distance T2 of the wavelength conversion unit 110 is larger than 1,000 micrometers, it is difficult to manufacture the semiconductor device package 400 in a small size.

In addition, the first separation distance T1 or the third separation distance T3 of the side wall of the wavelength conversion unit 110 may be provided at a thickness of a few micrometers to a few hundred micrometers. The larger the first separation distance T1 or the third separation distance T3 of the side wall of the wavelength conversion unit 110, the more the wavelength conversion efficiency may be enhanced.

For example, the first separation distance T1 of the wavelength conversion unit 110 may be provided to be 10 to 1,000 micrometers. When the second separation distance T2 of the wavelength conversion unit 110 is smaller than 10 micrometers, the wavelength conversion efficiency may be lowered, and when the first separation distance T1 of the wavelength conversion unit 110 is larger than 1,000 micrometers, it is difficult to manufacture the semiconductor device package 400 in a small size.

In addition, the third separation distance T3 of the wavelength conversion unit 110 may be provided to be 10 to 1,000 micrometers. When the third thickness T3 of the wavelength conversion unit 110 is smaller than 10 micrometers, the wavelength conversion efficiency may be lowered, and when the third thickness T3 of the wavelength conversion unit 110 is larger than 1,000 micrometers, it is difficult to manufacture the semiconductor device package 400 in a small size.

For example, the second separation distance T2 may be provided to be larger than the first separation distance T1 or the third separation distance T3. As another expression, the distance from the top surface of the semiconductor device 100 to the top surface of the wavelength conversion unit 110 may be provided to be larger than the distance from the side surface of the semiconductor device 100 to the outer surface of the wavelength conversion unit 110. As the second separation distance T2 is provided to be larger than the first separation distance T1 or the third separation distance T3, the wavelength conversion efficiency of the light extracted from the top surface of the semiconductor device 100 toward the top can be enhanced.

In addition, according to a first embodiment, the ratio between the second separation distance T2 and the first separation distance T1 or the ratio between the second separation distance T2 and the third separation distance T3 may be determined according to the wavelength conversion efficiency in the upper region of the wavelength conversion unit 110 and the wavelength conversion efficiency in the side wall region of the wavelength conversion unit 110.

For example, as the second separation distance T2 is provided to be equal to the first separation distance T1 or the third separation distance T3, a degree of light, of which the wavelength is converted in the upper portion of the wavelength conversion unit 110, becomes similar to a degree of light, of which the wavelength is converted on the side surfaces of the wavelength conversion unit 110, and thus light corresponding to the same color coordinates can be implemented in the both regions.

The ratio of the second separation distance to the first separation distance may be 1:0.01 to 1:100.

When the ratio between the first separation distance and the second separation distance is 1:0.01 or higher, the speed of light diffusing toward the side surface of the wavelength conversion unit 110 increases, and the efficiency of emission of light emitted toward the side surface of the semiconductor device 100 can be enhanced.

When the ratio between the first separation distance and the second separation distance is 1:100 or lower, the semiconductor device package is manufactured in a small size, and a process throughput can be secured.

The light corresponding to the same color coordinates in the both regions can be implemented by adjusting the wavelength conversion efficiency in the upper region of the wavelength conversion unit 110 and the wavelength conversion efficiency in the side wall region of the wavelength conversion unit 110.

The wavelength conversion unit 110 according to a first embodiment may include a resin, a wavelength conversion material and a scattering material. The wavelength conversion unit 110 may include a polymer resin in which a wavelength conversion material is scattered. In addition, the wavelength conversion unit 110 may include a scattering material distributed in the polymer resin.

For example, the wavelength conversion unit 110 may include at least one selected from a group including a light-transmitting epoxy resin, a silicon resin, a polyimide resin, a urea resin, and an acrylic resin. For example, the wavelength conversion unit 110 may include a silicon resin.

The wavelength conversion material provided in the wavelength conversion unit 110 may absorb light provided from the semiconductor device 100 and emit wavelength-converted light. For example, the wavelength conversion material may include any one or more among a fluorescent substance and a quantum dot (QD). For example, the fluorescent substance may include any one fluorescent material among the YAG series, TAG series, silicate series, sulfide series, and nitride series.

According to a first embodiment, a YAG series or TAG series fluorescent material may be selected among (Y, Tb, Lu, Sc, La, Gd, Sm)3(Al, Ga, In, Si, Fe)5(O, S)12:Ce, a silicate series fluorescent material may be selected among (Sr, Ba, Ca, Mg)2SiO4:(Eu, F, CI). In addition, a sulfide series fluorescent material may be selected among (Ca, Sr)S:Eu, (Sr, Ca, Ba)(Al, Ga)2S4:Eu, and a nitride series fluorescent material may be (Sr, Ca, Si, Al, O)N:Eu (e.g., CaAlSiN4:Eu β-SiAlON:Eu) or (Cax, My)(Si, Al)12(O, N)16 of Ca-α SiAlON:Eu series. At this point, M is at least a material among Eu, Tb, Yb and Er and may be selected among fluorescent materials satisfying 0.05<(x+y)<0.3, 0.02<x<0.27 and 0.03<y<0.3. A red fluorescent substance may be a nitride series fluorescent substance including N (e.g., CaAlSiN3: Eu) or a KSF(K2SiF6) fluorescent substance.

The wavelength conversion unit 110 may include a scattering material for scattering light inputted from the semiconductor device 100. For example, the wavelength conversion unit 110 may include light scattering particles such as TiO2. As the light inputted from the semiconductor device 100 is scattered and distributed by the scattering material provided in the wavelength conversion unit 110, the quantity of light extracted toward the side surface of the wavelength conversion unit 110 can be increased.

According to the semiconductor device package 400 according to a first embodiment, the semiconductor device package 400 includes the wavelength conversion unit 110 disposed on the top surface of the semiconductor device 100. The wavelength conversion unit 110 includes an upper region disposed on the top surface of the semiconductor device 100 at the second thickness T2. According to an embodiment, the light emitted from the top surface of the semiconductor device 100 toward the top by the upper region of the wavelength conversion unit 110 is effectively wavelength-converted by the wavelength conversion unit 110.

The wavelength conversion unit 110 according to a first embodiment may be disposed to contact with the top surface and side surfaces of the semiconductor device 100. The wavelength conversion unit 110 may sufficiently secure an area contacting with the light provided from the top surface and the side surfaces of the semiconductor device 100. Accordingly, the wavelength conversion unit 110 may receive sufficient quantity of light emitted from the semiconductor device 100, and wavelength-convert and provide the light.

A light control unit 120 according to a first embodiment may be disposed on the top surface of the wavelength conversion unit 110. For example, the light control unit 120 may be disposed to directly contact with the top surface of the wavelength conversion unit 110. The light control unit 120 may be disposed to be spaced apart from the top surface of the semiconductor device 100. The width of the light control unit 120 in a first direction may be provided to be larger than the width of the semiconductor device 100 in the first direction.

The light control unit 120 may reflect part of the light inputted from the wavelength conversion unit 110 and transmit part of the light. For example, the light control unit 120 may reflect part of white light inputted from the wavelength conversion unit 110 and transmit part of the white light. For example, the light control unit 120 may reflect part of the light of a blue wavelength band and the light of a yellow wavelength band inputted from the wavelength conversion unit 110 and transmit part of the light.

According to a first embodiment, white light may be emitted from the top surface of the light control unit 120 toward the top. In addition, white light may be emitted from the side surfaces of the wavelength conversion unit 110 toward the outside.

That is, according to the semiconductor device package 400 according to a first embodiment, as shown in FIGS. 1 to 3, white light may be emitted toward the four side surfaces surrounding the wavelength conversion unit 110 and toward the top of the light control unit 120. As another expression, the white light may be emitted toward the outside from the four side walls of the wavelength conversion unit 110 surrounding the four side surfaces of the semiconductor device 100.

In addition, the white light may be emitted toward the top from the top surface of the light control unit 120 disposed to directly contact with the top surface of the wavelength conversion unit 110.

For example, light of a blue wavelength band and light of a yellow wavelength band may be emitted toward the four side surfaces surrounding the wavelength conversion unit 110 and toward the top of the light control unit 120. As another expression, the light of a blue wavelength band and the light of a yellow wavelength band may be emitted toward the outside from the four side walls of the wavelength conversion unit 110 surrounding the four side surfaces of the semiconductor device 100.

In addition, light of a blue wavelength band and light of a yellow wavelength band may be emitted toward the top from the top surface of the light control unit 120 disposed to directly contact with the top surface of the wavelength conversion unit 110.

According to a first embodiment, the light control unit 120 is disposed on the top surface of the wavelength conversion unit 110 and is not disposed on the side surface of the wavelength conversion unit 110. Accordingly, part of the light wavelength-converted in the upper portion of the wavelength conversion unit 110 passes through the light control unit 120 and is emitted toward the top of the light control unit 120.

In addition, part of the light wavelength-converted in the upper portion of the wavelength conversion unit 110 may be reflected again by the light control unit 120 toward the bottom and emitted toward the side surface of the light control unit 120.

According to the semiconductor device package according to a first embodiment, wavelength conversion efficiency of the light emitted from the semiconductor device 100 can be enhanced by the wavelength conversion unit 110 disposed between the top surface of the semiconductor device 100 and the light control unit 120. For example, when the light control unit 120 is disposed to directly contact with the top surface of the semiconductor device 100, the quantity of light extracted from the semiconductor device 100 toward the top is reduced greatly. In addition, since the light reflected from the bottom surface of the light control unit 120 enters again into the semiconductor device 100, the quantity of lost light increases, and thus the light extraction efficiency of the semiconductor device 100 is remarkably lowered.

However, according to a first embodiment, as the bottom surface of the light control unit 120 is disposed to be spaced apart from the top surface of the semiconductor device 100, the quantity of light extracted toward the top of the semiconductor device 100 may be increased. In addition, as the bottom surface of the light control unit 120 is disposed to be spaced apart from the top surface of the semiconductor device 100, the light reflected from the bottom surface of the light control unit 120 propagates from the wavelength conversion unit 110 in the traverse direction, and the light emitted in the traverse direction of the wavelength conversion unit 110 is increased.

That is, the light reflected from the bottom surface of the light control unit 120 propagates from the wavelength conversion unit 110 in a direction parallel to the top surface of the semiconductor device 100, and the light emitted toward the side surface of the wavelength conversion unit 110 may be increased.

Like this, according to the semiconductor device package 400 according to a first embodiment, as the bottom surface of the light control unit 120 is disposed to be spaced apart from the top surface of the semiconductor device 100, the quantity of light extracted toward the top of the semiconductor device 100 is increased, and in addition, the quantity of light extracted from the side walls of the wavelength conversion unit 110 toward the outside is also increased.

According to a first embodiment, the light control unit 120 may transmit a quantity of light less than 90% of the white light inputted from the wavelength conversion unit 110. For example, the light control unit 120 may transmit a quantity of light 3 to 90% of the white light inputted from the wavelength conversion unit 110. Transmittance of the light control unit 120 for the incident light may be flexibly adjusted according to application examples of the semiconductor device package according to an embodiment.

According to the semiconductor device package 400 according to a first embodiment, the quantity of light emitted toward the top of the light control unit 120 and the quantity of light emitted from the side walls of the light control unit 120 toward the outside may be determined according to the transmittance of the incident light of the light control unit 120. For example, transmittance of the incident light of the light control unit 120 may be selected to uniformly make the quantity of light emitted toward the top of the light control unit 120 and the quantity of light emitted from each of the side walls of the light control unit 120 toward the outside. A method of adjusting the transmittance of the light control unit 120 will be further described below.

For example, the semiconductor device package 400 according to a first embodiment may be applied to a light source module including a light guide panel. The light source module according to an embodiment may be provided as, for example, a direct type light source module constituting a display device. At this point, when the transmittance of the light control unit 120 is lower than 3% of the incident light, an area where the semiconductor device package 400 is disposed may be seen as a dark point in the display device. In addition, when the transmittance of the light control unit 120 is higher than 90% of the incident light, a hot spot phenomenon of generating a strong bright point may occur in the area where the semiconductor device package 400 is disposed. Accordingly, transmittance of the light control unit 120 may be flexibly selected within a range of not generating a dark point or a hot spot. An example of the light source module to which the semiconductor device package 400 according to an embodiment is applied will be further described below.

Meanwhile, the light control unit 120 according to a first embodiment may include a resin of a series the same as that of a resin included in the wavelength conversion unit 110. For example, the wavelength conversion unit 110 may include a silicon-series resin, and the light control unit 120 may include a silicon molding compound. Like this, both the light control unit 120 and the wavelength conversion unit 110 are selected to include a silicon-series resin, the adhesive force is enhanced, and separation of the light control unit 120 and the wavelength conversion unit 110 can be prevented.

As the light control unit 120 and the wavelength conversion unit 110 include a resin of the same series, degradation in the adhesive force or separation of the two layers caused by the difference of thermal expansion coefficient can be prevented. For example, the difference of thermal expansion coefficient between the light control unit 120 and the wavelength conversion unit 110 may be selected to be less than 20%. When the difference of thermal expansion coefficient between the light control unit 120 and the wavelength conversion unit 110 is larger than 20%, there may be a problem in the adhesive force of the two layers.

In addition, the light control unit 120 according to a first embodiment may include an insulation material. For example, the light control unit 120 may include at least one selected from a group including a silicone molding compound (SMC) and an epoxy molding compound (EMC). The light control unit 120 may include a wavelength conversion material. The color coordinates of light passing through the light control unit 120 can be additionally adjusted through the wavelength conversion material provided in the light control unit 120.

In addition, the light control unit 120 may include a distributed Bragg reflector (DBR) layer. The light control unit 120 may include a DBR layer having a plurality of pairs alternately stacking a first layer having a first refractive index and a second layer having a second refractive index that is higher than the first refractive index. For example, both the first layer and the second layer may be a dielectric, and a low refractive index and a high refractive index of the first layer and the second layer may be refractive indexes relative to each other. The light control unit 120 may provide a DBR layer transmittance within a desired range by adjusting the number of pairs stacking the first layer and the second layer.

Meanwhile, the light control unit 120 according to a first embodiment may include a metal material. For example, the light control unit 120 may be formed of a transparent conductive oxide film. The light control unit 120 may select a transmittance within a specific range by adjusting the thickness of the transparent conductive oxide film.

For example, the light control unit 120 may include at least a material selected among Indium Tin Oxide (ITO), Indium Zinc Oxide (IZO), Aluminum Zinc Oxide (AZO), Aluminum Gallium Zinc Oxide (AGZO), Indium Zinc Tin Oxide (IZTO), Indium Aluminum Zinc Oxide (IAZO), Indium Gallium Zinc Oxide (IGZO), Indium Gallium Tin Oxide (IGTO), Antimony Tin Oxide (ATO), Gallium Zinc Oxide (GZO), and IZO Nitride (IZON).

In addition, the light control unit 120 may be provided as a metal layer. The light control unit 120 may include a metal layer which provides a plurality openings. Accordingly, the light control unit 120 may select a transmittance according to the arrangement, size of the like of the openings. For example, the light control unit 120 may include a single layer or a plurality of layers including at least any one material selected from a group including aluminum (Al), aluminum alloy (Al alloy), tungsten (W), copper (Cu), copper alloy (Cu alloy), molybdenum (Mo), silver (Ag), silver alloy (Ag alloy), gold (Au), gold alloy (Au alloy), chrome (Cr), titanium (Ti), titanium alloy (Ti alloy), moly-tungsten (MoW), moly-titanium (MoTi), and copper/moly-titanium (Cu/MoTi).

Meanwhile, the semiconductor device package 400 according to a first embodiment described with reference to FIGS. 1 to 3 is described on the basis of a case including the wavelength conversion unit 110 in which a wavelength conversion material and a light scattering material are provided. However, according to a semiconductor device package according to another embodiment, when scattering and propagation of light can be smoothly carried out in a resin of a basic matrix, the wavelength conversion unit may be implemented not to include a separate light scattering material and to include only a wavelength conversion material. The wavelength conversion unit 110 not including a separate light scattering material like this may be simply referred to as a wavelength conversion unit 110.

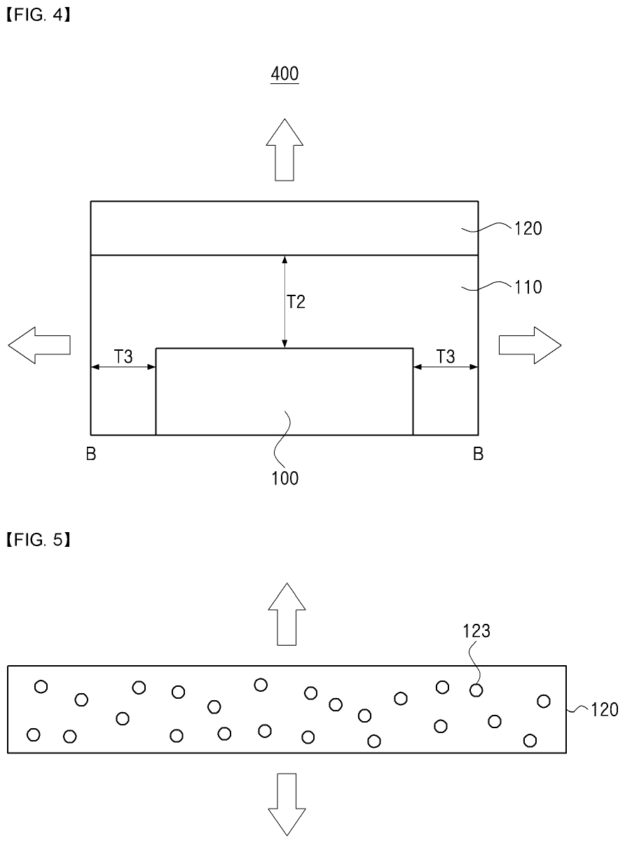

Then, a method of adjusting the transmittance by the light control unit 120 according to a first embodiment will be described with reference to FIGS. 5 to 7.

First, FIG. 5 is a view showing an example of a light control unit 120 applied to a semiconductor device package according to a first embodiment of the present invention. In describing the semiconductor device package according to a first embodiment with reference to FIG. 5, description of the elements duplicated to those described with reference to FIGS. 2 to 4 may be omitted.

A light control unit 120 according to a first embodiment may be formed of an insulation material as shown in FIG. 5. The light control unit 120 may include a resin. The light control unit 120 may include at least one selected from a group including, for example, a silicone molding compound (SMC) and an epoxy molding compound (EMC).

The light control unit 120 according to a first embodiment may include a resin of a series the same as that of a resin included in the wavelength conversion unit 110. For example, the wavelength conversion unit 110 may include a silicon-series resin, and the light control unit 120 may include a silicon molding compound (SMC). In addition, the wavelength conversion unit 110 may include an epoxy-series resin, and the light control unit 120 may include an epoxy molding compound (EMC). According to an embodiment, as the light control unit 120 and the wavelength conversion unit 110 are selected to include a resin of the same series, degradation in the adhesive force or separation of the two layers caused by the difference of thermal expansion coefficient can be prevented.

Meanwhile, as is known, reflectivity and transmittance of the silicon molding compound (SMC) and the epoxy molding compound (EMC) are changed according to thickness. Accordingly, when the light control unit 120 according to an embodiment is formed of a silicon molding compound (SMC) or an epoxy molding compound (EMC), a desired transmittance can be easily implemented by adjusting the thickness of the silicon molding compound (SMC) or the epoxy molding compound (EMC). For example, the light control unit 120 according to an embodiment may be provided at a thickness of a few micrometers to a few hundred micrometers. The silicon molding compound (SMC) and the epoxy molding compound (EMC) may include a reflective material such as TiO2. Accordingly, the silicon molding compound (SMC) and the epoxy molding compound (EMC) may show a different reflectivity or transmittance at the same thickness according to a degree of including a reflective material such as TiO2 or the like.

According to a first embodiment, the light control unit 120 may be selected to transmit a quantity of light less than 90% of incident white light. For example, the light control unit 120 may be selected to transmit a quantity of light 3 to 90% of the incident white light. Transmittance of the light control unit 120 for the incident light may be flexibly adjusted according to application examples of the semiconductor device package according to an embodiment.

In addition, the light control unit 120 may include a wavelength conversion material 123.

The color coordinates of light passing through the light control unit 120 can be additionally adjusted through the wavelength conversion material provided in the light control unit 120.

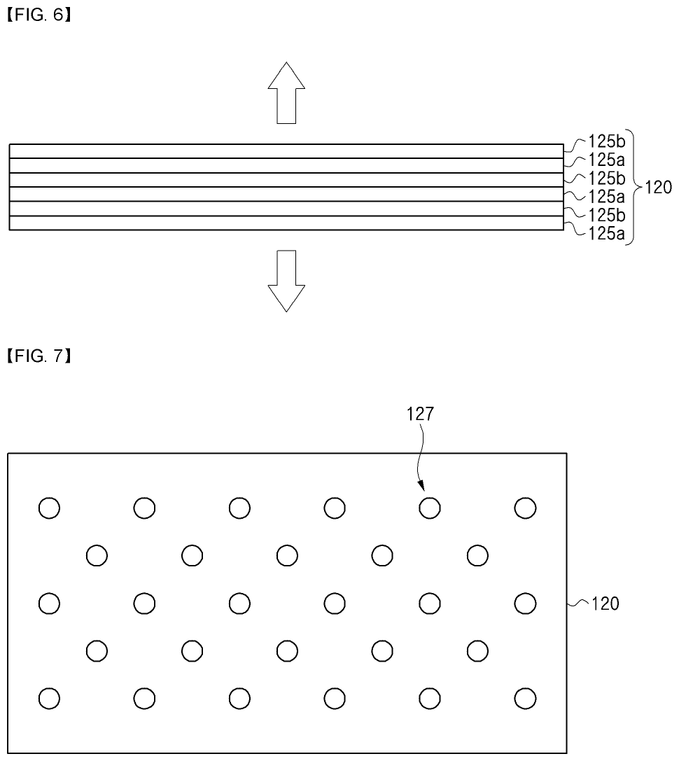

Meanwhile, FIG. 6 is a view showing another example of a light control unit applied to a semiconductor device package according to a first embodiment of the present invention. In describing the semiconductor device package according to a first embodiment with reference to FIG. 6, description of the elements duplicated to those described with reference to FIGS. 1 to 5 may be omitted.

A light control unit 120 according to a first embodiment may include a DBR layer as shown in FIG. 6. The light control unit 120 may include a first layer 125a having a first refractive index and a second layer 125b having a second refractive index.

The light control unit 120 may include a plurality of pairs alternately stacking the first layer 125a and the second layer 125b. At this point, for example, the first refractive index of the first layer 125a may be provided to be lower than the second refractive index of the second layer 125b. For example, the light control unit 120 may be provided as a DBR layer formed by stacking a SiO2 layer and a TiO2 layer as a plurality of layers.

The light control unit 120 may select a transmittance within a desired range by adjusting the number of pairs alternately stacking the first layer 125a and the second layer 125b. As is known, the DBR layer may adjust the transmittance according to selection of the thickness of each layer and the number of pairs. For example, it is known that when the light control unit 120 is provided to have a sufficient thickness and a sufficient number of pairs, the DBR layer may show a reflection characteristic close to total reflection. However, the light control unit 120 according to an embodiment may be implemented to provide a characteristic of partially reflecting and partially transmitting incident light.

According to a first embodiment, the light control unit 120 may transmit a quantity of light less than 90% of white light inputted from the wavelength conversion unit 110. For example, according an embodiment, the light control unit 120 may be selected to transmit a quantity of light 3 to 90% of the incident white light. Transmittance of the light control unit 120 for the incident light may be flexibly adjusted according to application examples of the semiconductor device package according to an embodiment.

Meanwhile, FIG. 7 is a view showing still another example of a light control unit applied to a semiconductor device package according to a first embodiment of the present invention. In describing the semiconductor device package according to a first embodiment with reference to FIG. 7, description of the elements duplicated to those described with reference to FIGS. 1 to 6 may be omitted.

A light control unit 120 according to a first embodiment may be provided as a metal layer as shown in FIG. 7. The light control unit 120 may include a plurality openings 127. Transmittance of light inputted into the light control unit 120 may be determined according to the arrangement, size, shape and the like of the openings 127. In addition, the light distribution characteristic of the light passing through the light control unit 120 may be determined by the arrangement, size, shape and the like of the openings 127.

According to a first embodiment, as the openings 127 are provided to have a different size or shape in each area, the light distribution characteristic of the light passing through the light control unit 120 may be diversely selected. For example, it may be implemented such that the number of openings 127 provided in the central area of the light control unit 120 is larger than the number of openings 127 provided in the peripheral area of the light control unit 120. In addition, it may be implemented such that the openings 127 provided in the central area of the light control unit 120 has a small size, and the openings 127 provided in the peripheral area of the light control unit 120 has a relatively large size. For example, the openings 127 may be provided at least in a shape selected from a group including a circle, an ellipse and a polygon.

For example, the light control unit 120 may include a single layer or a plurality of layers including at least any one material selected from a group including aluminum (Al), aluminum alloy (Al alloy), tungsten (W), copper (Cu), copper alloy (Cu alloy), molybdenum (Mo), silver (Ag), silver alloy (Ag alloy), gold (Au), gold alloy (Au alloy), chrome (Cr), titanium (Ti), titanium alloy (Ti alloy), moly-tungsten (MoW), moly-titanium (MoTi), and copper/moly-titanium (Cu/MoTi).

In addition, even when the light control unit 120 is provided as a single layer or a plurality of layers including a metal material, transmittance of the light control unit 120 may be controlled by adjusting the thickness of the light control unit 120 according to the characteristic of a material.

According to a first embodiment, the light control unit 120 may transmit a quantity of light less than 90% of white light inputted from the wavelength conversion unit 110. For example, the light control unit 120 may be selected to transmit a quantity of light 3 to 90% of the incident white light. Transmittance of the light control unit 120 for the incident light may be flexibly adjusted according to application examples of the semiconductor device package according to an embodiment.

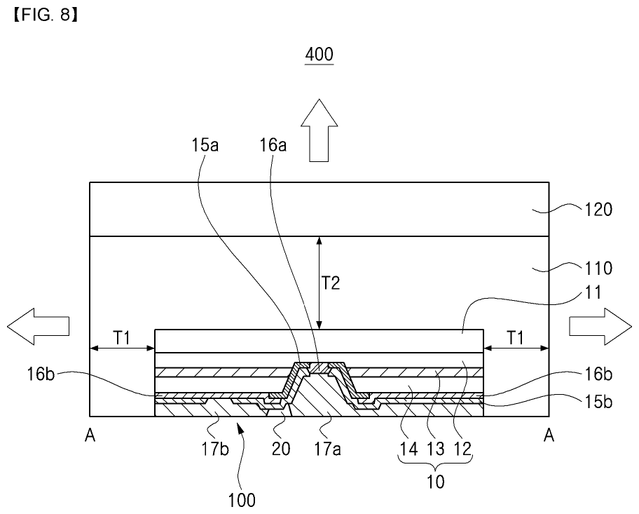

Meanwhile, FIG. 8 is a view showing another example of a semiconductor device package according to a first embodiment of the present invention. In describing the semiconductor device package according to an embodiment with reference to FIG. 8, description of the elements duplicated to those described with reference to FIGS. 1 to 7 may be omitted.

A semiconductor device package 400 according to an embodiment may include a semiconductor device 100, a wavelength conversion unit 110, and a light control unit 120 as shown in FIG. 8.

The semiconductor device 100 may include a light emitting structure 10 for providing light. The semiconductor device 100 may include a pad disposed under the light emitting structure 10 to be electrically connected to the light emitting structure 10. The semiconductor device 100 may include a first pad 17a electrically connected to a first conductive semiconductor layer 12 of the light emitting structure 10. The semiconductor device 100 may include a second pad 17b electrically connected to a second conductive semiconductor layer 14 of the light emitting structure 10. The first pad 17a and the second pad 17b may be provided on the bottom surface of the semiconductor device 100. For example, the first pad 17a and the second pad 17b of the semiconductor device 100 may be electrically connected to a circuit substrate that will be disposed in a lower portion through a flip chip bonding method. The semiconductor device 100 may include a substrate 11 disposed on the light emitting structure 10. For example, the substrate may be provided as a patterned sapphire substrate (PSS), in which a prominence and depression pattern is formed in an area contacting with the light emitting structure 10. For example, the substrate 11 may be a material suitable for growth of the light emitting structure 10 or may be a carrier wafer or a light-transmitting substrate. The substrate 11 may be formed of a material selected from a group including sapphire (Al2O3), SiC, GaAs, GaN, ZnO, Si, GaP, InP and Ge.

The wavelength conversion unit 110 according to an embodiment may be disposed on the top surface and the side surfaces of the semiconductor device 100. The wavelength conversion unit 110 may be disposed to directly contact with the top surface of the semiconductor device 100. The wavelength conversion unit 110 may be disposed to directly contact with the substrate 11. The wavelength conversion unit 110 may be disposed to directly contact with the side surfaces of the semiconductor device 100. The wavelength conversion unit 110 may be provided in a form surrounding all the four side surfaces and the top surface of the semiconductor device 100.

Accordingly, the wavelength conversion unit 110 may receive light extracted from the top surface of the semiconductor device 100 toward the top. In addition, the wavelength conversion unit 110 may receive light extracted from the side surface of the semiconductor device 100 toward the side surface.

The wavelength conversion unit 110 may receive light provided from the semiconductor device 100, and wavelength-convert and emit the light. The light wavelength-converted by the wavelength conversion unit 110 may propagate toward the top and the side surfaces of the wavelength conversion unit 110. The light propagated toward the side surface of the wavelength conversion unit 110 may be extracted from the outer surface of the wavelength conversion unit 110 toward the outside. In addition, the light propagated toward the top of the wavelength conversion unit 110 may enter the light control unit 120.

According to an embodiment, the light control unit 120 may be disposed on the wavelength conversion unit 110. The light control unit 120 may be disposed to directly contact with the top surface of the wavelength conversion unit 110. The light control unit 120 may be disposed to be spaced apart from the top surface of the semiconductor device 100. The light control unit 120 may partially transmit and partially reflect the light inputted from the wavelength conversion unit 110.

According to an embodiment, white light may be emitted from the top surface of the light control unit 120 toward the top. In addition, the white light may be emitted from the side surfaces of the wavelength conversion unit 110 toward the outside. That is, according to the semiconductor device package 400 according to a second embodiment, the white light may be emitted toward the four side surfaces surrounding the wavelength conversion unit 110 and toward the top of the light control unit 120. As another expression, the white light may be emitted toward the outside from the four side walls of the wavelength conversion unit 110 surrounding the four side surfaces of the semiconductor device 100. In addition, the white light may be emitted toward the top from the top surface of the light control unit 120 disposed to directly contact with the top surface of the wavelength conversion unit 110.

According to an embodiment, the second insulation layer 15b disposed in a lower region of the semiconductor device 100 may be provided as a DBR layer having a good reflection characteristic. Accordingly, the light generated by the semiconductor device 100 may be efficiently emitted toward the outside through the side surfaces and the top surface of the semiconductor device 100. The light emitted toward the side surface of the semiconductor device 100 may be wavelength-converted in the side wall region of the wavelength conversion unit 110. In addition, the light emitted toward the top surface of the semiconductor device 100 may be wavelength-converted in the upper region of the wavelength conversion unit 110.

According to the semiconductor device package according to an embodiment, wavelength conversion efficiency of the light emitted from the semiconductor device 100 can be improved by the wavelength conversion unit 110 disposed between the top surface of the semiconductor device 100 and the light control unit 120. For example, when the light control unit 120 is disposed to directly contact with the top surface of the semiconductor device 100, the quantity of light extracted from the semiconductor device 100 toward the top is reduced greatly. In addition, since the light reflected from the bottom surface of the light control unit 120 enters again inside the semiconductor device 100, the quantity of lost light increases, and thus the light extraction efficiency of the semiconductor device 100 is remarkably lowered.

However, according to an embodiment, as the bottom surface of the light control unit 120 is disposed to be spaced apart from the top surface of the semiconductor device 100, the quantity of light extracted toward the top of the semiconductor device 100 may be increased. In addition, as the bottom surface of the light control unit 120 is disposed to be spaced apart from the top surface of the semiconductor device 100, the light reflected from the bottom surface of the light control unit 120 propagates from the wavelength conversion unit 110 in the traverse direction, and the light emitted in the traverse direction of the wavelength conversion unit 110 is increased.

Like this, according to the semiconductor device package 400 according to an embodiment, as the bottom surface of the light control unit 120 is disposed to be spaced apart from the top surface of the semiconductor device 100, the quantity of light extracted toward the top of the semiconductor device 100 is increased, and in addition, the quantity of light extracted from the side walls of the wavelength conversion unit 110 toward the outside is also increased.

According to an embodiment, the light control unit 120 may transmit a quantity of light less than 90% of white light inputted from the wavelength conversion unit 110. For example, the light control unit 120 may transmit a quantity of light 3 to 90% of the white light inputted from the wavelength conversion unit 110. Transmittance of the light control unit 120 for the incident light may be flexibly adjusted according to application examples of the semiconductor device package according to an embodiment.

According to the semiconductor device package 400 according to an embodiment, the quantity of light emitted toward the top of the light control unit 120 and the quantity of light emitted from the side walls of the light control unit 120 toward the outside may be determined according to the transmittance of the incident light of the light control unit 120. For example, the transmittance of the incident light of the light control unit 120 may be selected to uniformly make the quantity of light emitted toward the top of the light control unit 120 and the quantity of light emitted from each of the side walls of the light control unit 120 toward the outside.

In addition, according to the semiconductor device package 400 according to an embodiment, the larger the thickness of the substrate 11, the more the quantity of the light extracted toward the side surface of the semiconductor device 100 increases. For example, the thickness of the substrate 11 may be provided at a thickness of a few micrometers to a few hundred micrometers. The substrate 11 may be provided at a thickness of 10 to 1,000 micrometers. When the substrate 11 is provided to be thinner than 10 micrometers, light extraction efficiency toward the side surface may be lowered, and when the substrate 11 is provided to be thicker than 1,000 micrometers, it is difficult to manufacture the semiconductor device package 400 in a small size.

According to an embodiment, as a method of improving extraction of light at the semiconductor device 100, a prominence and depression structure may be provided on the top surface of the substrate 11. In addition, as a method of improving extraction of light at the semiconductor device 100, a prominence and depression structure may be provided in a region where the substrate 11 and the light emitting structure 10 contact with each other. In addition, as a method of improving extraction of light at the semiconductor device 100, a prominence and depression structure may be provided on the side surfaces of the light emitting structure 10. In addition, as a method of improving extraction of light at the semiconductor device 100, a prominence and depression structure may be provided in a region where the semiconductor device 100 and the wavelength conversion unit 110 contact with each other.

Meanwhile, as an example, a method of manufacturing a semiconductor device package according to an embodiment may be formed through a process described below. For example, a method of manufacturing a semiconductor device package according to an embodiment may be created in a kind of chip scale package (CSP) method.

First, a plurality of semiconductor devices 100 may be disposed on a temporary substrate to be spaced apart from each other. In addition, a wavelength conversion unit 110 may be formed on the plurality of semiconductor devices 100. The wavelength conversion unit 110 may formed on the plurality of semiconductor devices 100. In addition, the wavelength conversion unit 110 may be formed between the plurality of semiconductor devices 100 disposed to be spaced apart from each other.

Next, a light control unit 120 may be formed on the wavelength conversion unit 110. In addition, the plurality of semiconductor devices 100 disposed to be spaced apart from each other may be cut along the lines formed between the semiconductor devices 100. Subsequently, individual semiconductor device packages may be manufactured by removing the temporary substrate from the plurality of semiconductor devices 100 separated from each other.

In addition, according to another embodiment, individual semiconductor device packages separated from each other may be manufactured by first removing the temporary substrate after the light control unit 120 is formed and then cutting the plurality of semiconductor devices 100 disposed to be spaced apart from each other along the lines formed between the semiconductor devices 100.

Like this, according to the method of manufacturing a semiconductor device package according to an embodiment, there is an advantage of simplifying the manufacturing process and reducing the manufacturing cost.

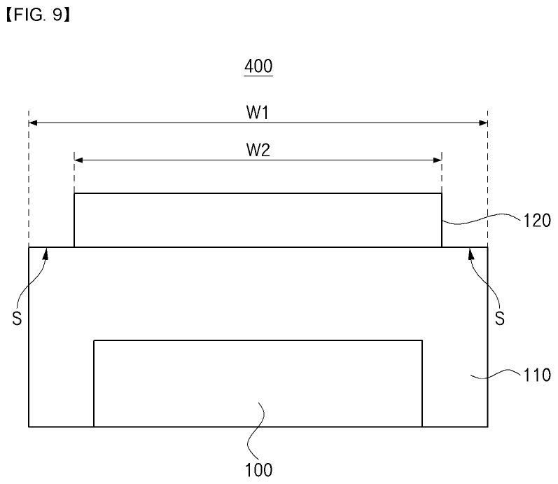

Meanwhile, FIG. 9 is a view showing still another example of a semiconductor device package according to a first embodiment of the present invention. In describing a semiconductor device package according to a first embodiment with reference to FIG. 9, description of the elements duplicated to those described with reference to FIGS. 1 to 8 may be omitted.

A semiconductor device package 400 according to an embodiment may include a semiconductor device 100, a wavelength conversion unit 110, and a light control unit 120 as shown in FIG. 9.

The semiconductor device 100 may include a light emitting structure 10 for providing light. The semiconductor device 100 may include a first pad 17a and a second pad 17b disposed on the bottom surface and electrically connected to the light emitting structure 10.

The semiconductor device 100 may include the first pad 17a electrically connected to a first conductive semiconductor layer 12 of the light emitting structure 10 and the second pad 17b electrically connected to a second conductive semiconductor layer 14 of the light emitting structure 10. The semiconductor device 100 may include a substrate disposed on the light emitting structure 10. For example, the substrate may be provided as a patterned sapphire substrate (PSS), in which a prominence and depression pattern is formed in a region contacting with the light emitting structure 10.

The wavelength conversion unit 110 according to an embodiment may be disposed on the top surface and the side surfaces of the semiconductor device 100. The wavelength conversion unit 110 may be disposed to directly contact with the top surface of the semiconductor device 100. The wavelength conversion unit 110 may be disposed to directly contact with the side surfaces of the semiconductor device 100. The wavelength conversion unit 110 may be provided in a form surrounding all the four side surfaces and the top surface of the semiconductor device 100.

Accordingly, the wavelength conversion unit 110 may receive light extracted from the top surface of the semiconductor device 100 toward the top. In addition, the wavelength conversion unit 110 may receive light extracted from the side surfaces of the semiconductor device 100 toward the side surface.

The wavelength conversion unit 110 may receive light provided from the semiconductor device 100 and wavelength-convert and emit the light. The light wavelength-converted by the wavelength conversion unit 110 may propagate toward the top and the side surfaces of the wavelength conversion unit 110. The light propagated toward the side surface of the wavelength conversion unit 110 may be extracted from the outer surface of the wavelength conversion unit 110 toward the outside. In addition, the light propagated toward the top of the wavelength conversion unit 110 may enter the light control unit 120.

According to an embodiment, the light control unit 120 may be disposed on the wavelength conversion unit 110. The light control unit 120 may be disposed to directly contact with the top surface of the wavelength conversion unit 110. The light control unit 120 may be disposed to be spaced apart from the top surface of the semiconductor device 100. The light control unit 120 may partially transmit and partially reflect the light inputted from the wavelength conversion unit 110.

According to an embodiment, white light may be emitted from the top surface of the light control unit 120 toward the top. In addition, the white light may be emitted from the side surfaces of the wavelength conversion unit 110 toward the outside. That is, according to the semiconductor device package 400 according to an embodiment, the white light may be emitted toward the four side surfaces surrounding the wavelength conversion unit 110 and toward the top of the light control unit 120. As another expression, the white light may be emitted toward the outside from the four side walls of the wavelength conversion unit 110 surrounding the four side surfaces of the semiconductor device 100. In addition, the white light may be emitted toward the top from the top surface of the light control unit 120 disposed to directly contact with the top surface of the wavelength conversion unit 110.

According to the semiconductor device package 400 according to an embodiment, wavelength conversion efficiency of the light emitted from the semiconductor device 100 can be enhanced by the wavelength conversion unit 110 disposed between the top surface of the semiconductor device 100 and the light control unit 120. For example, when the light control unit 120 is disposed to directly contact with the top surface of the semiconductor device 100, the quantity of light extracted from the semiconductor device 100 toward the top is reduced greatly. In addition, since the light reflected from the bottom surface of the light control unit 120 enters again inside the semiconductor device 100, the quantity of lost light increases, and thus the light extraction efficiency of the semiconductor device 100 is remarkably lowered.

However, according to an embodiment, as the bottom surface of the light control unit 120 is disposed to be spaced apart from the top surface of the semiconductor device 100, the quantity of light extracted toward the top of the semiconductor device 100 may be increased. In addition, as the bottom surface of the light control unit 120 is disposed to be spaced apart from the top surface of the semiconductor device 100, the light reflected from the bottom surface of the light control unit 120 propagates from the wavelength conversion unit 110 in the traverse direction, and the light emitted in the traverse direction of the wavelength conversion unit 110 is increased.

Like this, according to the semiconductor device package 400 according to an embodiment, as the bottom surface of the light control unit 120 is disposed to be spaced apart from the top surface of the semiconductor device 100, the quantity of light extracted toward the top of the semiconductor device 100 is increased, and in addition, the quantity of light extracted from the side walls of the wavelength conversion unit 110 toward the outside is also increased.

Meanwhile, according to the semiconductor device package 400 according to an embodiment, as shown in FIG. 11, the width w2 of the light control unit 120 may be provided to be smaller than the width w1 of the wavelength conversion unit 110. The width w2 of the bottom surface of the light control unit 120 may be provided to be smaller than the width w1 of the top surface of the wavelength conversion unit 110. Accordingly, in the region S where the light control unit 120 is not provided, the light propagating from the top surface of the wavelength conversion unit 110 toward the top may be extracted toward the outside without passing through the light control unit 120.

According to an embodiment, the orientation angle of a beam emitted from the semiconductor device package 400 toward the side surface may be adjusted by adjusting the width of the region S where the light control unit 120 is not provided. For example, the light control unit 120 may cover the entire area of the wavelength conversion unit 110 or may cover about 30% of the width w1 of the wavelength conversion unit 110.

Like this, according to an embodiment, the orientation angle for emitting light from the side surface of the semiconductor device package 400 may be determined from the ratio w2/w1 of the width w2 of the light control unit 120 to the width w1 of the wavelength conversion unit 110. For example, the ratio w2/w1 of the width w2 of the light control unit 120 to the width w1 of the wavelength conversion unit 110 may be selected as 30 to 100%. In addition, according to an embodiment, transmittance of the light control unit 120 may be provided as 0%. At this point, the light control unit 120 may be simply referred to as a reflection unit. According to a third embodiment, the ratio w2/w1 of the width w2 of the light control unit 120 to the width w1 of the wavelength conversion unit 110, the transmittance of the light control unit 120 for incident light and the like may be flexibly adjusted according to application examples of the semiconductor device package according to a third embodiment.

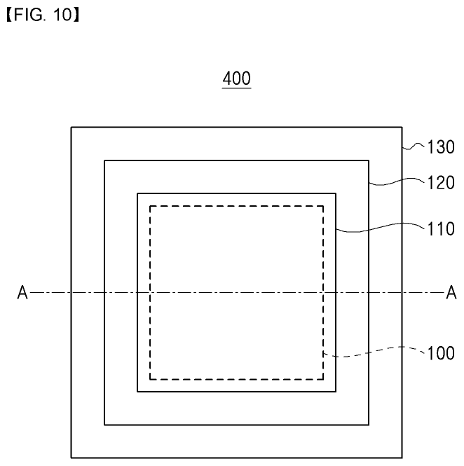

Meanwhile, FIG. 10 is a view showing a semiconductor device package according to a second embodiment of the present invention.

FIG. 10 is a plan view showing a semiconductor device package according to a second embodiment of the present invention, and FIG. 11 is a cross-sectional view taken along the line A-A′ in FIG. 10. As shown in FIG. 10, a semiconductor device package according to a second embodiment of the present invention includes a semiconductor device 100, a reflection member 130 disposed on the side surface of the semiconductor device 100 and having an inclined surface 70, a light control unit 120 disposed between the inclined surface of the reflection member 130 and the side surface of the semiconductor device 100 and having a first wavelength conversion unit 60 on the top, and a second wavelength conversion unit 40 disposed on the entire top surface of the semiconductor device 100 and/or in a portion of the top surface of the first wavelength conversion unit 60.

Since the first and second wavelength conversion units mean the wavelength conversion unit described above and do not include a scattering material, they are referred to as a wavelength conversion unit.

In describing the semiconductor device package according to an embodiment with reference to FIG. 10, description of the elements duplicated to those described with reference to FIGS. 1 to 9 may be omitted.

The semiconductor device 100 may include various kinds of electronic devices such as a light emitting device, a light receiving device and the like, and the light emitting device may be a UV light emitting device or a blue light emitting device. The light emitting device emits light by recombination of electrons and holes, and the wavelength of the light is determined by an energy gap unique to a material, and the light emitting device may emit light within a wavelength range from the infrared band to the visible light band. The semiconductor device 100 may be a flip chip.

The wavelength conversion unit 110 may be disposed on the semiconductor device 100. The wavelength conversion unit 110 may have a function of converting the wavelength of light emitted from the wavelength conversion unit 110 to the outside when light input from the semiconductor device 100 into the wavelength conversion unit 110 is emitted to the outside.

The wavelength conversion unit 110 may be formed of a polymer resin including a wavelength conversion material. The polymer resin may include at least one or more among a light-transmitting epoxy resin, a silicon resin, a polyimide resin, a urea resin, and an acrylic resin. However, it is not limited thereto and may be diversely selected according to selection of a user.

The wavelength conversion material may be a fluorescent substance. The wavelength conversion material may include at least one or more among sulfide-based, oxide-based and nitride-based compounds. However, the wavelength conversion material is not limited thereto and may be diversely selected to implement a color desired by a user.

For example, when the semiconductor device 100 emits light of an ultraviolet wavelength band, a green fluorescent substance, a blue fluorescent substance or a red fluorescent substance may be selected as the fluorescent substance. When the semiconductor device 100 emits light of a green wavelength band, a combination of a yellow fluorescent substance or a red fluorescent substance and a green fluorescent substance or a combination of a yellow fluorescent substance, a red fluorescent substance and a green fluorescent substance may be selected as the fluorescent substance.

The reflection member 130 reflects side surface light of the semiconductor device 100. The reflected light may enter the semiconductor device 100 again or may be outputted to one side of the semiconductor device 100.

The reflection member 130 may include at least one or more among an epoxy resin, a polyamide resin, a urea resin, and an acrylic resin. However, it is not limited thereto and may be diversely selected according to selection of a user.

The reflection member 130 may include reflection particles. The reflection particles may be TiO2 or SiO2.

The reflection member 130 according to a second embodiment may be formed of a white silicon resin including reflection particle TiO2.

The reflection member 130 may be disposed around the semiconductor device 100, where the light control unit 120 is disposed, and has an inclined surface 70 facing the side surface of the light control unit 120.

The light control unit 120 may have a refractive index different from the refractive index of the semiconductor device 100. The light control unit 120 may include at least one or more among an epoxy resin, a silicon resin, a polyamide resin, a urea resin, and an acrylic resin. However, it is not limited thereto and may be diversely selected according to selection of a user.

The light control unit 120 may have a refractive index different from the refractive index of the semiconductor device 100 and may improve the efficiency of extracting light emitted from the semiconductor device 100. In addition, since the light emitted from the semiconductor device 100 and entering the light control unit 120 is diffused in the light control unit 120 due to refraction of light generated at the interface between the semiconductor device 100 and the light control unit 120, uniformity of light intensity can be improved in the light output area of the semiconductor device package.

A light control unit 120 according to a second embodiment may be disposed on the four side surfaces of the semiconductor device 100. When the substrate of the semiconductor device 100 is removed, the light control unit 120 may be disposed on the side surfaces of the light emitting structure 10. The height of the light control unit 120 may be equal to the height of the semiconductor device 100.

A first wavelength conversion unit 112 may be disposed on the light control unit 120. The first wavelength conversion unit 112 may have a function of converting the wavelength of light emitted from the light control unit 120 to the outside when light inputted from the semiconductor device 100 into the light control unit 120 is emitted to the outside.

The first wavelength conversion unit 112 may be formed of a polymer resin including a wavelength conversion material. The polymer resin may include at least one or more among a light-transmitting epoxy resin, a silicon resin, a polyimide resin, a urea resin, and an acrylic resin. However, it is not limited thereto and may be diversely selected according to selection of a user.

In addition, the wavelength conversion material of the first wavelength conversion unit 112 may be disposed to be precipitated at one side of the first wavelength conversion unit 112 or may be disposed to be distributed across the entire area of the first wavelength conversion unit 112. However, it is not limited thereto and may be diversely selected according to selection of a user.

The wavelength conversion material may be a fluorescent substance. The wavelength conversion material may include at least one or more among sulfide-based, oxide-based and nitride-based compounds. However, the wavelength conversion material is not limited thereto and may be diversely selected to implement a color desired by a user.

For example, when the semiconductor device 100 emits light of an ultraviolet wavelength band, a green fluorescent substance, a blue fluorescent substance or a red fluorescent substance may be selected as the fluorescent substance. When the semiconductor device 100 emits light of a green wavelength band, a combination of a yellow fluorescent substance or a red fluorescent substance and a green fluorescent substance or a combination of a yellow fluorescent substance, a red fluorescent substance and a green fluorescent substance may be selected as the fluorescent substance.

The configuration of the first wavelength conversion unit 112 is a configuration of an embodiment for converting the wavelength of light of the semiconductor device 100 which emits blue light into the wavelength of white light. However, it is not limited thereto, and the first wavelength conversion unit 112 may be freely configured according to selection of a user.

Thickness of the first wavelength conversion unit 112 may be 10 to 50% of the thickness of the semiconductor device 100. When the thickness of the first wavelength conversion unit 112 is less than 10% of the thickness of the semiconductor device 100, there is no big difference in the effect of improving the speed of light, and it takes a long time to precipitate the wavelength conversion material, and thus it is undesirable from the aspect of processing time.

When the thickness of the first wavelength conversion unit 112 is 50% or more of the thickness of the semiconductor device 100, the effect of improving the speed of light cannot be expected since the wavelength conversion material is not sufficiently precipitated.

A second wavelength conversion unit 114 may be disposed on the entire top surface of the semiconductor device 100 and/or in a portion of the top surface of the first wavelength conversion unit 112.

The second wavelength conversion unit 114 may be vertically overlapped on the top surface of the wavelength conversion unit 112 in a range less than 50% of the width of the first wavelength conversion unit.

If the area of the second wavelength conversion unit 114 vertically overlapped with the wavelength conversion unit 112 exceeds 50% of the width of the first wavelength conversion unit, the range of the area, in which the wavelength of side surface light is converted twice while the light passes through the wavelength conversion unit 112 and the second wavelength conversion unit 114, is excessively wide, and it is disadvantage from the aspect of efficiency of speed of light. Therefore, it is efficient to set the range of the vertically overlapping area to be less than 50% of the width of the first wavelength conversion unit.

The second wavelength conversion unit 114 may be formed of a polymer resin including a wavelength conversion material. The polymer resin may include at least one or more among a light-transmitting epoxy resin, a silicon resin, a polyimide resin, a urea resin, and an acrylic resin. However, it is not limited thereto and may be diversely selected according to selection of a user.

The wavelength conversion material may be a fluorescent substance. The wavelength conversion material may include at least one or more among sulfide-based, oxide-based and nitride-based compounds. However, the wavelength conversion material is not limited thereto and may be diversely selected to implement a color desired by a user.

For example, when the semiconductor device 100 emits light of an ultraviolet wavelength band, a green fluorescent substance, a blue fluorescent substance or a red fluorescent substance may be selected as the fluorescent substance. When the semiconductor device 100 emits light of a green wavelength band, a combination of a yellow fluorescent substance or a red fluorescent substance and a green fluorescent substance or a combination of a yellow fluorescent substance, a red fluorescent substance and a green fluorescent substance may be selected as the fluorescent substance.

The configuration of the second wavelength conversion unit 114 is a configuration of an embodiment for converting the wavelength of light of the semiconductor device 100 which emits blue light into the wavelength of white light. However, it is not limited thereto, and the first wavelength conversion unit 112 may be freely configured according to selection of a user.

The wavelength conversion material of the first wavelength conversion unit 112 may have a content of 50 to 200% with respect to the total weight of the polymer resin of the first wavelength conversion unit 112.

The wavelength conversion material of the second wavelength conversion unit 114 may have a content of 150 to 200% with respect to the total weight of the polymer resin of the second wavelength conversion unit 114.

When the wavelength conversion material of the first wavelength conversion unit 112 has a content less than 50% with respect to the total weight of the polymer resin of the first wavelength conversion unit 112, the effect of enhancing the efficiency of speed of light cannot be expected, and when the wavelength conversion material of the first wavelength conversion unit 112 has a content of 200% or larger with respect to the total weight of the polymer resin of the first wavelength conversion unit 112, there is no big difference from the aspect of enhancing the efficiency of speed of light.

When the wavelength conversion material of the second wavelength conversion unit 114 has a content less than 150% with respect to the total weight of the polymer resin of the second wavelength conversion unit 114, the second wavelength conversion unit 114 may not sufficiently convert the wavelength of light inputted into the wavelength conversion unit 110 when the light is emitted to the outside, and when the wavelength conversion material of the second wavelength conversion unit 114 has a content of 200% or more with respect to the total weight of the polymer resin of the second wavelength conversion unit 114, the second wavelength conversion unit 114 may sufficiently convert the wavelength of the light with a content less than 200% with respect to the total weight of the polymer resin, and thus a content above that is meaningless.

The CIE coordinates is a very important index in a semiconductor device package, and since a difference in the CIE coordinates leads to a result of showing a different color to the eyes of a person when it is driven in the same color, the semiconductor device package should have the same CIE coordinates throughout the package.

Although the semiconductor device package of the present invention may expect improvement in the efficiency of speed of light compared with the semiconductor device package of the prior art, if the content ratio of the wavelength conversion material of the first wavelength conversion unit 112 is set to be the same as that of the second wavelength conversion unit 114, the CIE coordinates could be changed in each region of the package due to the difference in the quantity of light on the side surfaces and the top surface of the semiconductor device.

Accordingly, in order to have the same CIE coordinates throughout the package, the content ratio of the wavelength conversion material of the first wavelength conversion unit 112 should be set to be different from that of the second wavelength conversion unit 114, and a desirable combination considering a color rendering index or the like should be found.

For example, the first wavelength conversion unit 112 and the second wavelength conversion unit 114 may have a different content ratio of the wavelength conversion material within a range of a wavelength conversion material content to manufacture a semiconductor device package having a color rendering index of 60 to 90, which is generally used in the present.

In an embodiment of the present invention, a semiconductor device package having a color rendering index (CRI) of 60 to 75 can be obtained when the first wavelength conversion unit 112 has a content ratio of the wavelength conversion material of 55 to 65% with respect to the total weight of polymer resin and the second wavelength conversion unit 114 has a content ratio of the wavelength conversion material of 170 to 190% with respect to the total weight of polymer resin.

A semiconductor device package having a color rendering index (CRI) of 80 to 90 can be obtained when the first wavelength conversion unit 112 has a content ratio of the wavelength conversion material of 150 to 200% with respect to the total weight of polymer resin and the second wavelength conversion unit 114 has a content ratio of the wavelength conversion material of 150 to 200% with respect to the total weight of polymer resin.

When a semiconductor device package is manufactured, a combination of the content ratio of the wavelength conversion materials of the first wavelength conversion unit 112 and the second wavelength conversion unit 114 considering the same CIE coordinates, in addition to the color rendering index, may be selected.

To manufacture a semiconductor device package of the same CIE coordinates, the maxing ratio of the polymer resin and the wavelength conversion material of the first wavelength conversion unit 112 may be 20 to 40% of the maxing ratio of the polymer resin and the wavelength conversion material of the second wavelength conversion unit 114. To obtain the mixing ratio, the content of the fluorescent substance with respect to the total weight of the polymer resin of the second wavelength conversion unit 114 may be higher than the content of the fluorescent substance with respect to the total weight of the polymer resin of the first wavelength conversion unit 112.

The reflection member 130 may be disposed on the side surfaces of the semiconductor device 100. The reflection member 130 may include a first side surface closest to the side surface of the semiconductor device 100 and a second side surface facing the first side surface. The first side surface or the second side surface may have an inclined surface. The light control unit 120 may be disposed between the first side surface and the side surface of the semiconductor device 100 and may include an inclined surface 70 corresponding to the inclined surface of the first side surface. As the light emitted from the side surfaces of the semiconductor device 100 is reflected toward the top through the inclined surface 70 of the first side surface included in the reflection member 130, the light extraction efficiency can be enhanced. The inclined surface 70 may have an angle of 15 to 75 degrees with respect to the top surface of the first pad 17a and the second pad 17b.

When the angle of the inclined surface 70 with respect to the top surface of the first pad 17a and the second pad 17b is 15 degrees or lower, it is undesirable since the quantity of light entering the light control unit 120 decreases as the orientation angle decreases, and when the angle of the inclined surface 70 is 75 degrees or higher, it is inefficient from the aspect of speed of light since the relative speed of light decreases.

Table 1 is a table showing the measurements of the relative speed of light and the orientation angle according to the tilt angle of the inclined surface 70.

TABLE 1

| | Inclined | Relative | Orienta- |
|---|---|---|---|
| | surface angle | speed of light | tion angle |
| | (°) | (%) | (°) |
| First experimental example | 15 | 112 | 135 |
| Second experimental example | 30 | 106 | 130 |
| Third experimental example | 45 | 100 | 128 |
| Fourth experimental example | 60 | 94 | 124 |
| Fifth experimental example | 75 | 88 | 120 |

As shown in Table 1, it is confirmed that as the angle of the inclined surface 70 increases, the relative speed of light decreases, and the orientation angle is lowered.

Accordingly, a desired speed of light and a desired orientation angle may be obtained by adjusting the angle of the inclined surface 70.

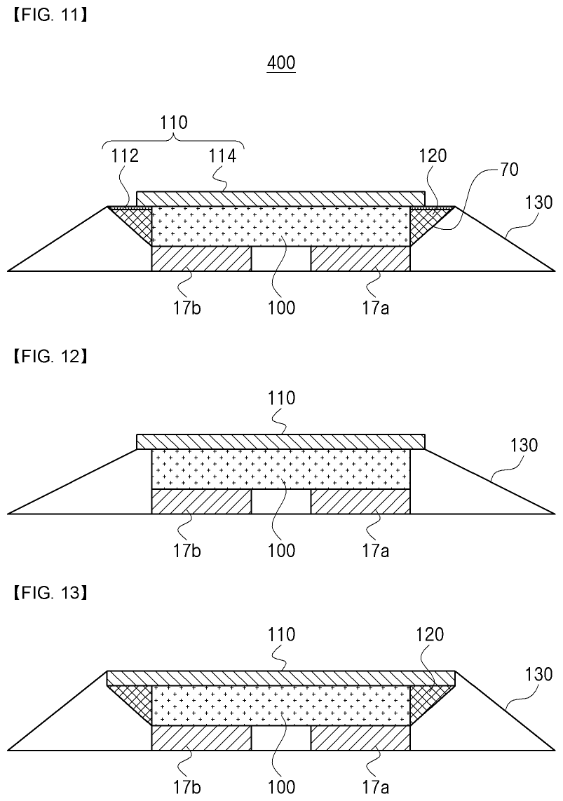

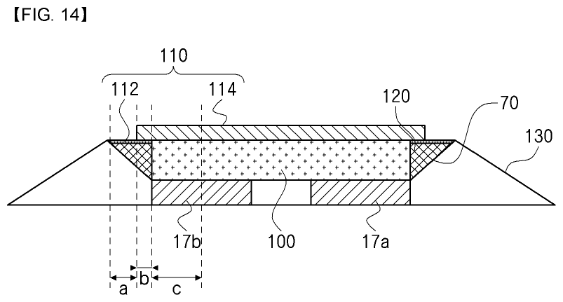

Table 2 is a table comparing the speed of light of a semiconductor device package according to a first comparative example and a second comparative example shown in FIGS. 12 and 13 and the speed of light of a semiconductor device package according to a second embodiment.

FIG. 12 is a cross-sectional view showing a semiconductor device package according to a first comparative example. As shown in FIG. 12, a semiconductor device package according to a first comparative example includes a semiconductor device 100, a wavelength conversion unit 110, and a reflection member 130.

The semiconductor device 100 may include various kinds of electronic devices such as a light emitting device, a light receiving device and the like, and the light emitting device may be a UV light emitting device or a blue light emitting device. The light emitting device emits light by recombination of electrons and holes, and the wavelength of the light is determined by an energy gap unique to a material, and the light emitting device may emit light within a wavelength range from the infrared band to the visible light band. The semiconductor device 100 may be a flip chip.

The wavelength conversion unit 110 may be disposed on the semiconductor device 100. The wavelength conversion unit 110 may have a function of converting the wavelength of light emitted from the wavelength conversion unit 110 to the outside when light input from the semiconductor device 100 into the wavelength conversion unit 110 is emitted to the outside.

The wavelength conversion unit 110 may be formed of a polymer resin including a wavelength conversion material. The polymer resin may include at least one or more among a light-transmitting epoxy resin, a silicon resin, a polyimide resin, a urea resin, and an acrylic resin. However, it is not limited thereto and may be diversely selected according to selection of a user.

The wavelength conversion material may be a fluorescent substance. The wavelength conversion material may include at least one or more among sulfide-based, oxide-based and nitride-based compounds. However, the wavelength conversion material is not limited thereto and may be diversely selected to implement a color desired by a user.

For example, when the semiconductor device 100 emits light of an ultraviolet wavelength band, a green fluorescent substance, a blue fluorescent substance or a red fluorescent substance may be selected as the fluorescent substance. When the semiconductor device 100 emits light of a green wavelength band, a combination of a yellow fluorescent substance or a red fluorescent substance and a green fluorescent substance or a combination of a yellow fluorescent substance, a red fluorescent substance and a green fluorescent substance may be selected as the fluorescent substance.

The reflection member 130 reflects side surface light of the semiconductor device 100. The reflected light may enter the semiconductor device 100 again or may be outputted to one side of the semiconductor device 100.

The reflection member 130 may include at least one or more among an epoxy resin, a polyamide resin, a urea resin, and an acrylic resin. However, it is not limited thereto and may be diversely selected according to selection of a user.

The reflection member 130 may include reflection particles. The reflection particles may be TiO2 or SiO2.

FIG. 13 is a cross-sectional view showing a semiconductor device package according to a second comparative example.

As shown in FIG. 13, a semiconductor device package according to a second comparative example includes a semiconductor device 100, a wavelength conversation unit 110, a light control unit 120, and a reflection member 130.

The semiconductor device 100, the wavelength conversation unit 110 and the reflection member 130 of the semiconductor device package according to a second comparative example are the same as those of the conventional semiconductor device package shown in FIG. 2, and detailed description thereof will be omitted.

The light control unit 120 may have a refractive index different from the refractive index of the semiconductor device 100. The light control unit 120 may include at least one or more among an epoxy resin, a silicon resin, a polyamide resin, a urea resin, and an acrylic resin. However, it is not limited thereto and may be diversely selected according to selection of a user.

The light control unit 120 may have a refractive index different from the refractive index of the semiconductor device 100 and may improve the efficiency of extracting light emitted from the semiconductor device 100. In addition, since the light emitted from the semiconductor device 100 and entering the light control unit 120 is diffused in the light control unit 120 due to refraction of light generated at the interface between the semiconductor device 100 and the light control unit 120, uniformity of light intensity can be improved in the light output area of the semiconductor device package.

TABLE 2

| | Relative | |
|---|---|---|
| | speed of | |
| | light | |
| Items | [%] | Remarks |
| FIG. 2 (First comparative example) | 100 | Ref |
| FIG. 3 (Second comparative example) | 106.2 | Apply light control |
| | | unit |
| FIG. 4 (Present invention) | 107.5 | Apply first wavelength |
| | | conversion unit |

As shown in Table 2, it is known that in the semiconductor device package according to the present invention, the speed of light is improved by about 1.3% compared with the semiconductor device packages according to the first comparative example and the second comparative example.

Compared with the semiconductor device package structures according to the comparative examples shown in FIGS. 12 and 13, the semiconductor device package structure according to a second embodiment could have improved the efficiency of speed of light through the first wavelength conversion unit 112.

It is confirmed that the efficiency of speed of light and the semiconductor device characteristics are improved through the semiconductor device package according to a second embodiment.

FIG. 14 is a view describing a semiconductor device package according to a second embodiment of the present invention.

As shown in FIG. 14, the wavelength conversion material included in the first wavelength conversion unit 112 and the second wavelength conversion unit 114 is a fluorescent substance, and when the first wavelength conversion unit and the second wavelength conversion unit are divided into region ‘a’ having only the first wavelength conversion unit, region ‘b’ in which a portion of the first wavelength conversion unit is vertically overlapped with a portion of the second wavelength conversion unit, and region ‘c’ having only the second wavelength conversion unit, each of the three regions may have a different fluorescent substance content ratio (an average content ratio in the case of region ‘b’).

Since the first wavelength conversion unit 112 and the second wavelength conversion unit 114 are overlapped in region ‘b’, non-uniformity of the color coordinates can be mitigated at the boundary of the semiconductor device region having only the second wavelength conversion unit 114 and a light-transmitting member having only the first wavelength conversion unit 112.

The fluorescent substance content ratios of region ‘a’, region ‘b’, and region ‘c’ with respect to the total weight of the polymer resin can be compared by calculating the fluorescent substance content of region ‘b’ as an average of the fluorescent substance content ratios with respect to the total weights of two different polymer resins of the first wavelength conversion unit 112 and the second wavelength conversion unit 114.

Comparing the content ratios of the fluorescent substance to the polymer resin of the regions (an average content ratio in the case of region ‘b’), a relative content ratio of region ‘c’>region ‘b’>region ‘a’ or region ‘c’>region ‘a’>region ‘b’ may be provided. A semiconductor device package of CIE coordinates desired by a user can be manufactured through the relative content ratio.

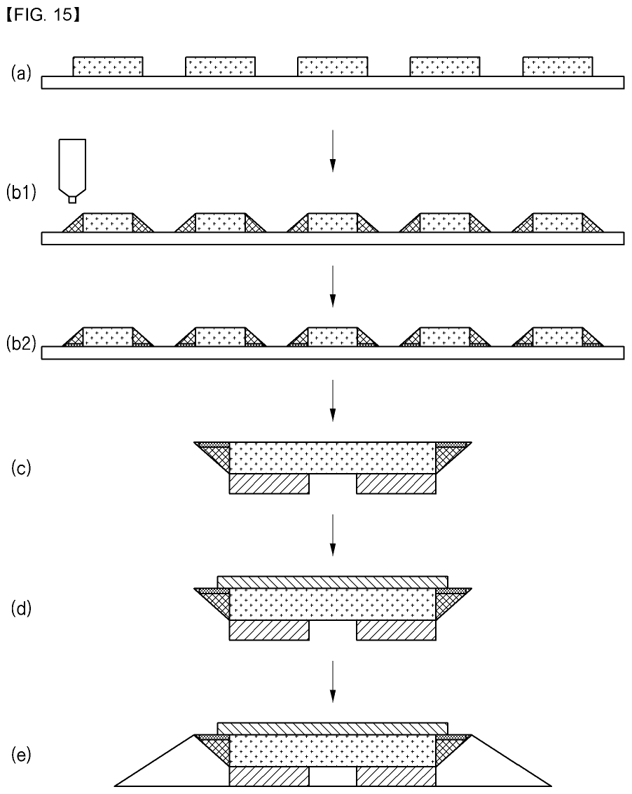

Meanwhile, the process of manufacturing a semiconductor device package according to a second embodiment will be described with reference to FIG. 15.

FIGS. 15(a) to 15(e) are views showing the process of manufacturing a semiconductor device package according to a second embodiment of the present invention.

As shown in FIGS. 15(a) and 15(b1), the light control unit 120 may be formed by disposing a plurality of semiconductor devices 100 on a silicon tape and injecting a resin including a wavelength conversion material on the side surface of each semiconductor device 100. The vertical cross-section of a light transmitting member 20 may be a triangular shape, and an adhesive performing the mechanical and electrical contact and heat dissipating function on the top surface of the silicon tape makes it possible to form the vertical cross-section of the light control unit 120 in a triangular shape. The inclined surface 70 may be provided as the vertical cross-section of the light control unit 120 is fixed to the side surface of the semiconductor device 100 in a triangular shape.

As shown in FIG. 15(b2), the first wavelength conversion unit 112 may be formed by precipitating the wavelength conversion material of the light control unit 120.

The precipitated wavelength conversion material is a fluorescent substance, and although the precipitated wavelength may be one among a sulfide-based compound, an oxide-based compound and a nitride-based compound, it is not limited thereto.

Thickness of the first wavelength conversion unit 112 may be 10 to 50% of the thickness of the semiconductor device 100. When the thickness of the first wavelength conversion unit 112 is less than 10% of the thickness of the semiconductor device 100, there is no big difference in the effect of improving the speed of light, and it takes a long time to precipitate the wavelength conversion material, and thus it is undesirable from the aspect of processing time.

When the thickness of the first wavelength conversion unit 112 is 50% or more of the thickness of the semiconductor device 100, the effect of improving the speed of light cannot be expected since the wavelength conversion material is not sufficiently precipitated.

As shown in FIG. 15(c), after turning over the semiconductor device 100, in which the light control unit 120 is formed on the side surface, and taking off the silicon tape, the semiconductor device 100 may be mechanically and electrically connected to the substrate by attaching the semiconductor device 100 on the substrate. As shown in FIG. 15(d), the second wavelength conversion unit 114 including a wavelength conversion material is attached on the top surface of the semiconductor device 100 using a glue. The wavelength conversion material may be a fluorescent substance.

The fluorescent substance may include at least one or more among a sulfide-based compound, an oxide-based compound and a nitride-based compound. However, it is not limited thereto and may be diversely selected to implement a color desired by a user.

For example, when the semiconductor device 100 emits light of an ultraviolet wavelength band, a green fluorescent substance, a blue fluorescent substance or a red fluorescent substance may be selected as the fluorescent substance. When the semiconductor device 100 emits light of a green wavelength band, a combination of a yellow fluorescent substance or a red fluorescent substance and a green fluorescent substance or a combination of a yellow fluorescent substance, a red fluorescent substance and a green fluorescent substance may be selected as the fluorescent substance.

Subsequently, as shown in FIG. 15(e), the semiconductor device package may be completed by injecting a reflection member 130 in the lower portion of the semiconductor device 100 and between the light control unit 120 and the substrate.

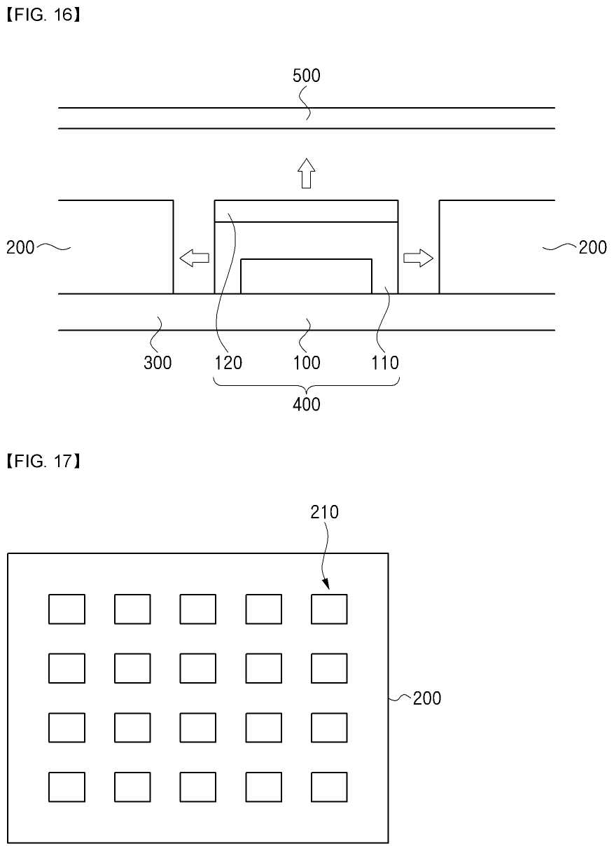

A light source module will be described with reference to FIGS. 16 and 17, as an example of applying the semiconductor device package 400 according to an embodiment. FIG. 16 is a view showing a light source module according to an embodiment of the present invention, and FIG. 17 is a view showing an example of a light guide panel applied to a light source module according to an embodiment of the present invention. In describing the light source module according to an embodiment with reference to FIGS. 16 and 17, description of the elements duplicated to those described with reference to FIGS. 1 to 15 may be omitted.

As shown in FIG. 16, a light source module according to an embodiment may include a light guide panel 200, a circuit substrate 300, and a semiconductor device package 400. The light guide panel 200 and the semiconductor device package 400 may be disposed on the circuit substrate 300.

The semiconductor device package 400 may be electrically connected to the circuit substrate 300. For example, the semiconductor device package 400 may include a first pad and a second pad disposed on the bottom surface. The semiconductor device package 400 may be electrically connected to the circuit substrate 300 in a flip chip bonding method.

The semiconductor device package 400 may include a semiconductor device 100, a wavelength conversion unit 110, and a light control unit 120. The wavelength conversion unit 110 may be disposed on the side surfaces and the top surface of the semiconductor device 100. The light control unit 120 may be disposed on the top surface of the wavelength conversion unit 110. The wavelength conversion unit 110 may receive light provided from the semiconductor device 100 and emit wavelength-converted light. The light wavelength-converted by the wavelength conversion unit 110 may be emitted to the side surfaces of the wavelength conversion unit 110 and inputted into the light guide panel 200. In addition, the light wavelength-converted by the wavelength conversion unit 110 may pass through the light control unit 120 and be emitted toward the top.

For example, thickness of the semiconductor device package 400 may be provided to be the same as the thickness of the light guide panel 200. In addition, thickness of the semiconductor device package 400 may also be provided to be thinner the thickness of the light guide panel 200. When the thickness of the semiconductor device package 400 is larger than the thickness of the light guide panel 200, the hot spot phenomenon described above may occur on the light guide panel 200.

The light guide panel 200 according to an embodiment may include a plurality of through holes 210 as shown in FIG. 17. The through holes 210 may refer to the regions in which both the top surface and the bottom surface of the light guide panel 200 are open. The top surface of the circuit substrate 300 disposed under the light guide panel 200 may be exposed through the through holes 210. In addition, the semiconductor device packages 400 may be disposed in the plurality of through holes 210. As the semiconductor device packages 400 are disposed in the plurality of through holes 210, light can be provided to the light guide panel 200.

According to an embodiment, the semiconductor device package 400 may provide light toward the side surface of the light guide panel 200. Light may be provided toward the four side surfaces and the top surface of the semiconductor device package 400. The light extracted toward the side surface of the semiconductor device package 400 may be inputted into the side surface of the light guide panel 200 disposed to be adjacent thereto. The light inputted into the light guide panel 200 may be converted into a surface light source while propagating through the light guide panel 200 and provided toward the top of the light guide panel 200.

In addition, according to an embodiment, as described above, the quantity of light emitted toward the top of the semiconductor device package 400 and the quantity of light emitted toward the side surface of the semiconductor device package 400 can be controlled. For example, the light emitted toward the top of the semiconductor device package 400 can be uniformly controlled by adjusting the thickness of the wavelength conversion unit 100 disposed on the semiconductor device 100 and the thickness of the light control unit 120.

The number of through holes 210 provided in the light guide panel 200 may be proportional to the number of semiconductor device packages 400. In addition, the number of through holes 210 provided in the light guide panel 200 may be the same as the number of semiconductor device packages 400 disposed in the light guide panel 200.

When the number of through holes 210 and the number of semiconductor device packages 400 disposed in the light guide panel 200 are the same, the price of a product can be lowered by reducing the number of semiconductor device packages 400 disposed in the through holes 210 of the light guide panel 200.

For example, the distance between the centers of the through holes 210 provided in the light guide panel 200 can be adjusted as one of methods for reducing the number of semiconductor device packages 400 disposed in the through holes 210 of the light guide panel 200 and securing uniformity and luminance of light emitted toward the top of the light guide panel 200. The distance between the centers of the through holes 210 may include a first distance of a first direction and a second distance perpendicular to the first direction. As the first distance and the second distance are adjusted according to the size and shape of the semiconductor device packages 400 and the through holes 210, uniformity and luminance of the light emitted toward the top of the light guide panel 200 can be adjusted.

In addition, at least one or more of the centers of the first direction or the centers of the second direction of the semiconductor device packages 400 disposed in the plurality of through holes 210 and the centers of the first direction or the centers of the second direction of the through holes 210 may match in the first direction or the second direction. Alternately, the centers of the first direction or the centers of the second direction of the through holes 210 and the centers of the first direction or the centers of the second direction of the semiconductor device packages 400 may match within 10% of the width of the first direction or the width of the second direction of the through holes 210. Therefore, according to an embodiment, uniformity of the light emitted from the semiconductor device package 400 and entering the light guide panel 200 can be secured.

The light provided toward the top of the light guide panel 200 may enter a diffusion plate 500. The diffusion plate 500 may be disposed on the light guide panel. In addition, the light provided toward the top of the semiconductor device package 400 may enter the diffusion plate 500. The diffusion plate 500 may provide uniform light toward the top of the diffusion plate 500 using the light provided from the light guide panel 200 and the light provided from the semiconductor device package 400. For example, the diffusion plate 500 may supply light for displaying images on a display panel that will be disposed on the diffusion plate 500. The light source module according to an embodiment may be provided as, for example, a direct type light source module constituting a display device.

According to the light source module according to an embodiment, as shown in FIGS. 16 and 17, the semiconductor device packages 400 may be disposed in the plurality of through holes 210 provided in the light guide panel 200, respectively. At this point, the top surface of the semiconductor device package 400 may be disposed to be lower than or as high as the top surface of the light guide panel 200.

When the top surface of the semiconductor device package 400 is disposed to be higher than the top surface of the light guide panel 200, part of the light emitted toward the side surface of the semiconductor device package 400 may not propagate toward the side surface of the light guide panel 200 and may propagate toward the top of the light guide panel 200. If part of the light emitted toward the side surface of the semiconductor device package 400 propagates toward the top of the light guide panel 200, uniformity of the light propagating toward the top through the light guide panel 200 may be deteriorated.

According to an embodiment, to prevent occurrence of the problems, the top surface of the semiconductor device package 400 is disposed to be lower than or as high as the top surface of the light guide panel 200. Accordingly, the light provided by the emission of light from the side surface of the semiconductor device package 400 may uniformly propagate into the light guide panel 200 through the side surface of the light guide panel 200.

The light source module according to an embodiment may be provided in the form of a thin film. The semiconductor device package 400 applied to the light source module according to an embodiment may provide light toward the side surface. In addition, the light emitted from the semiconductor device package 400 toward the side surface may directly enter the side surface of a facing and neighboring light guide panel 200. That is, the semiconductor device package 400 does not need a separate optical means, such as a lens, a prism or the like, for propagating emitted light toward the side surface.

In an existing light source module, a separate lens or the like is additionally disposed on the semiconductor device package to generate light propagating toward the side surface. As a lens or the like is additionally disposed on the semiconductor device package which generate and provide light, the light emitted from the semiconductor device package toward the top may propagate toward the side surface through the lens.

However, as described above, according to the light source module according to an embodiment, since light propagating from the semiconductor device package 400 itself toward the side surface can be provided, a separate optical means is not required. Accordingly, the light source module according to an embodiment may be provided in the form of a thin film. In addition, since a separate optical means, such as a lens or the like, is not required, the manufacturing cost of the light source module can be reduced.

As described above with reference to FIGS. 1 to 15, the semiconductor device package 400 according to an embodiment may provide light toward the top and the side surfaces of the semiconductor device package 400. According to an embodiment, the light control unit 120 may transmit a quantity of light less than 90% of white light inputted from the wavelength conversion unit 110. For example, the light control unit 120 may transmit a quantity of light between 3 and 90% of white light inputted from the wavelength conversion unit 110. Accordingly, a quantity of light between 3 and 90% of white light inputted from the wavelength conversion unit 110 into the light control unit 120 may be transmitted toward the top of the semiconductor device package 400. The transmittance of the light control unit 120 for the incident light may be selected considering the optical transmission characteristic of the light guide panel 200 and the light diffusion characteristic of the diffusion plate 500.

At this point, when the transmittance of the light control unit 120 is lower than 3% of the incident light, an area where the semiconductor device package 400 is disposed may be seen as a dark point from the top of the diffusion plate 500. In addition, when the transmittance of the light control unit 120 is higher than 90% of the incident light, seen from the top of the diffusion plate 500, a hot spot phenomenon of generating a strong bright point may occur in the area where the semiconductor device package 400 is disposed. Accordingly, the transmittance of the light control unit 120 may be flexibly selected within a range of not generating a dark point or a hot spot. An example of the light source module to which the semiconductor device package 400 according to an embodiment is applied will be further described below.

Accordingly, according to the light source module according to an embodiment, uniform light may be provided toward the top across the entire area of the diffusion plate 500 by selecting a quantity of light which can propagate toward the top of the semiconductor device package 400, considering the optical characteristic of the light guide panel 200 and the optical characteristic of the diffusion plate 500.

In addition, optimal conditions of the thickness, width, transmittance and the like of the constitutional components constituting the semiconductor device package 400 according to an embodiment may be determined by the size of the through holes 210 provided in the light guide panel 200, the disposing distance between the plurality of through holes 210, the distance between the side surface of the through hole 210 and the side surface of the semiconductor device package 400 disposed in the through hole 210, the disposing distance between the plurality of semiconductor device packages 400, and the like.

In addition, the semiconductor device package of the present invention may further include an optical member, such as a light guide panel, a prism sheet, a diffusion sheet or the like, to function as a backlight unit. In addition, the semiconductor device package of the present invention may be applied to a display device, a lighting device or a directing device.

At this point, the display device may include a bottom cover, a reflection plate, a light emitting module, a light guide panel, an optical sheet, a display panel, an image signal output circuit, and a color filter. The bottom cover, the reflection plate, the light emitting module, the light guide panel, and the optical sheet may configure a backlight unit.

The reflection plate is disposed on the bottom cover, and the light emitting module emits light. The light guide panel is disposed in front of the reflection plate to guide light emitted from the light emitting module to the front side, and the optical sheet includes a prism sheet or the like and is disposed in front of the light guide panel. The display panel is disposed in front of the optical sheet, and the image signal output circuit supplies image signals to the display panel, and the color filter is disposed in front of the display panel.

In addition, the lighting device may include a light source module including a substrate and a semiconductor device package of the present invention, a heat sink unit for dissipating heat of the light source module, and a power supply unit for processing or converting an electrical signal received from the outside and providing the signal to the light source module. In addition, the lighting device may include lamps, head lamps, street lamps and the like.

In addition, a camera flash of a mobile terminal may include a light source module including a semiconductor device package of the present invention.

Although the present invention has been described above, those skilled in the art may recognize that the present invention may also be embodied in other forms while maintaining the spirit and essential features of the present invention.

Although the scope of the present invention will be defined by the claims, it should be interpreted that configurations directly derived from the disclosure of the claims and all changes and modified forms derived from the equivalent configurations thereof are also included in the scope of the present invention.

1. A semiconductor device package comprising:
a semiconductor device including a substrate, a light emitting structure, and a first pad and a second pad electrically connected to the light emitting structure;
a wavelength conversion unit disposed to surround a top surface and side surfaces of the semiconductor device;
a light control unit disposed on the wavelength converting unit;
a second wavelength conversion unit disposed on the top surface of the semiconductor device and including a wavelength conversion material; and
a first wavelength conversion unit disposed on a light-transmitting member and including a wavelength conversion material, wherein
the wavelength conversion unit includes a top surface having a first separation distance from the semiconductor device in a vertical direction, and side surfaces having a second separation distance from the semiconductor device in a horizontal direction, and
a content ratio of the wavelength conversion material of the first wavelength conversion unit is different from that of the second wavelength conversion unit.

2. The package according to claim 1, wherein the semiconductor device package includes first light emitted toward the top surface and second light emitted toward the side surfaces, wherein intensity of the first light is higher than intensity of the second light.

3. The package according to claim 1, wherein the first separation distance is larger than the second separation distance.

4. The package according to claim 1, wherein a ratio of the second separation distance to the first separation distance is between 1:0.01 and 1:100.

5. The package according to claim 1, wherein the wavelength conversion unit includes a resin, a wavelength conversion material, and a scattering material, and the light control unit includes a resin of a series the same as that of a resin included in the wavelength conversion unit.

6-10. (canceled)

11. The package according to claim 1, wherein the second wavelength conversion unit disposed in a region of a top surface of the first wavelength conversion unit is vertically overlapped on the top surface of the first wavelength conversion unit within a range less than 50% of a width of the first wavelength conversion unit.

12. The package according to claim 1, wherein the wavelength conversion material is a fluorescent substance, and when the first wavelength conversion unit and the second wavelength conversion unit are divided into region ‘a’ having only the first wavelength conversion unit, region ‘b’ in which a portion of the first wavelength conversion unit is vertically overlapped with a portion of the second wavelength conversion unit, and region ‘c’ having only the second wavelength conversion unit, each of the three regions may have a different fluorescent substance content ratio (an average content ratio in the case of region ‘b’).

13. The package according to claim 12, wherein a content ratio of the fluorescent substance to a polymer resin of each region (an average content ratio in the case of region ‘b’) is a relative content ratio of region ‘c’>region ‘b’>region ‘a’ or region ‘c’>region ‘a’>region ‘b’.

14. The package according to claim 1, wherein the inclined surface has an angle of 15 to 75 degrees with respect to a top surface of the first pad and the second pad.

15. A light source module comprising:
a circuit substrate;
a light guide panel disposed on the circuit substrate, through which incident light passes; and
a semiconductor device package electrically connected to the circuit substrate, wherein
the semiconductor device package includes:
a semiconductor device including a substrate, a light emitting structure, and a first pad and a second pad electrically connected to the light emitting structure;
a wavelength conversion unit disposed to surround a top surface and side surfaces of the semiconductor device;
a light control unit disposed on the wavelength converting unit;
a second wavelength conversion unit disposed on the top surface of the semiconductor device and including a wavelength conversion material; and
a first wavelength conversion unit disposed on a light-transmitting member and including a wavelength conversion material, wherein
the wavelength conversion unit includes a top surface having a first separation distance from the semiconductor device in a vertical direction, and side surfaces having a second separation distance from the semiconductor device in a horizontal direction, and
a content ratio of the wavelength conversion material of the first wavelength conversion unit is different from that of the second wavelength conversion unit.

16. The module according to claim 15, wherein thickness of the semiconductor device package is equal to or smaller than thickness of the light guide panel.

17. The module according to claim 15, wherein the light guide panel includes a plurality of through holes.

18. The module according to claim 17, wherein the number of through holes is proportional to the number of semiconductor device packages.

19. The module according to claim 15, wherein the semiconductor device package provides light toward a side surface of the light guide panel.

20. The module according to claim 15, further comprising a diffusion plate for receiving light passing through the light guide panel through one surface and diffusing the incident light to the other surface.

21. The module according to claim 15, wherein a top surface of the semiconductor device package is disposed at a lower or equal height compared with a top surface of the light guide panel.

22. The module according to claim 17, wherein at least one or more among centers of a first direction or centers of a second direction of the semiconductor device packages disposed in the plurality of through holes and centers of the first direction or the centers of the second direction of the through holes match in the first direction of the second direction.

23. The module according to claim 17, wherein centers of a first direction or centers of a second direction of the through holes and centers of the first direction or the centers of the second direction of the semiconductor device packages match within 10% of a width of the first direction or a width of the second direction of the through holes.

24. A display device comprising:
a backlight unit including a light source module and emitting light;
a display panel disposed in front of the backlight unit;
an image signal output circuit for supplying image signals to the display panel; and
a color filter disposed in front of the display panel, wherein
the light source module includes:
a circuit substrate;
a light guide panel disposed on the circuit substrate, through which incident light passes; and
a semiconductor device package electrically connected to the circuit substrate,
wherein
the semiconductor device package includes:
a semiconductor device including a substrate, a light emitting structure, and a first pad and a second pad electrically connected to the light emitting structure;
a wavelength conversion unit disposed to surround a top surface and side surfaces of the semiconductor device;
a light control unit disposed on the wavelength converting unit;
a second wavelength conversion unit disposed on the top surface of the semiconductor device and including a wavelength conversion material; and
a first wavelength conversion unit disposed on a light-transmitting member and including a wavelength conversion material, wherein
the wavelength conversion unit includes a top surface having a first separation distance from the semiconductor device in a vertical direction, and side surfaces having a second separation distance from the semiconductor device in a horizontal direction, and
a content ratio of the wavelength conversion material of the first wavelength conversion unit is different from that of the second wavelength conversion unit.

25. The device according to claim 24, wherein the backlight unit further includes a bottom cover, a reflection plate, and an optical sheet, wherein
the reflection plate is disposed on the bottom cover,
the light guide panel is disposed in front of the reflection plate to guide light emitted from the light emitting module to a front side, and
the optical sheet is disposed in front of the light guide panel.
